(19) United States
(12) Patent Application Publication
(10) Pub. No.: US 2026/0133241 A1
(43) Pub. Date: May 14, 2026

(54) SYSTEM FOR DETECTING A PARTIAL DISCHARGE AND A METHOD OF OPERATING THEREOF

(71) Applicant: OSENSA INNOVATIONS CORP., Burnaby (CA)

(72) Inventors: Jeffrey Charles ANDLE, Orlando, FL (US); Peter RIZUN, Harrison Hot Springs (CA); Daryl G. JAMES, Coquitlam (CA)

(21) Appl. No.: 19/199,250

(22) Filed: May 5, 2025

Related U.S. Application Data
(63) Continuation-in-part of application No. 19/197,943, filed on May 2, 2025.
(63) Continuation-in-part of application No. 19/197,947, filed on May 2, 2025.
(60) Provisional application No. 63/642,863, filed on May 5, 2024.
(60) Provisional application No. 63/642,867, filed on May 5, 2024.

(51) Int. Cl. G01R 31/14; G01R 31/12; G01R 31/28

(52) U.S. Cl. CPC G01R 31/14; G01R 31/1227; G01R 31/2822

(57) ABSTRACT

A system for detecting a partial discharge in electric power equipment is disclosed. The has a sensor located so as to receive ultra-high frequency signals related to the partial discharge, which has antenna and two or more envelope detectors connected to the antenna through respective bandpass filters. A measurement hub is located so as to allow safe access and has a computational platform. The sensor and the measurement hub are interconnected by a cable. The antenna derives UHF signals in different frequency bands, and envelope detectors simultaneously detect respective baseband signals from the UHF signals. Cable transmits the baseband signals on corresponding signal lines of the cable from the sensor to the measurement hub. A corresponding method is also provided.

### CROSS-REFERENCE TO RELATED APPLICATIONS

The present application claims the benefit from U.S. provisional application Ser. Nos. 63/642,863 (OSN-001-US-prov) and 63/642,867 (OSN-002-US-prov) filed on May 5, 2024;

The present application is also a Continuation-in-Part of U.S. patent application Ser. No. 19/197,943 filed on May 2, 2025 (OSN-001-US);

The present application is also a Continuation-in-Part of U.S. patent application Ser. No. 19/197,947 filed on May 2, 2025 (OSN-004-US);

the entire contents of the above noted patent applications being incorporated herein by reference.

### FIELD OF THE INVENTION

The present invention is related to monitoring partial discharge (PD) for electric power equipment, in particular, to ultra-high frequency monitor of partial discharge for electric power equipment, and system and method therefor.

### BACKGROUND OF THE INVENTION

Partial Discharge is a primary failure mode for electric power systems. Within the electric power industry there are numerous classes of equipment that can have partial discharge leading to a full arc fault failure. It is common in the power industry to discuss medium voltage as 1000 Vrms to 69 k Vrms and high voltage as 70 k Vrms and up. Safety standards ignore this distinction and call all voltages over 1000 Vrms ‘high voltage’. In terms of numbers of assets, the largest classes of equipment are switchgear, transformers, bus ducts, and the like in the medium voltage range for power generation and distribution. These assets are often typified by a metal enclosed hazardous “process area” containing the medium voltage and a relatively low hazard “instrumentation compartment”.

While the instrumentation compartment can be accessed for service and updating, the process area cannot be accessed without either a total shutdown of the electrical power equipment or the use of extensive personal protective equipment by highly trained service technicians.

When measuring a parameter related to asset health, it is necessary that at least some of the instrumentation (“the sensor”) be located at or near the point of the asset that is expected to fail. For medium voltage switchgear and in the context of partial discharge, the priorities have been (a) the cables entering and exiting the switchgear or transformers, (b) the bushings of the physical switch or the inter-winding insulation of the transformer, and (c) the spacers of bus bars between or through process area compartments.

There is a long-established need for a low-cost partial discharge (PD) sensor and system for medium and high voltage switchgear and bus duct monitoring. Existing PD sensors are either too complex or too low functioning for many practical applications.

### SUMMARY OF THE INVENTION

It is an object of the present invention to provide a method and system detecting a partial discharge, and a method of operating the system for detecting the partial discharge.

According to one aspect of the invention, there is provided a system for detecting a partial discharge (PD) in electric power equipment. The system comprises a sensor and a measurement hub interconnected through a cable. The sensor is located to enable receiving ultra-high frequency (UHF) signals that includes potential PD-induced electromagnetic (EM) signals. The sensor comprises at least one antenna and at least two envelope detectors (linear or logarithmic) connected to at least one of the at least one antenna through respective bandpass filters. The measurement hub comprises a computational platform and is located so as to allow safe access.

The bandpass filters are configured to derive at least two signals in two different frequency bands. The at least two envelope detectors are configured to simultaneously detect from the at least two signals respective at least two baseband signals. The cable is configured to transmit the at least two baseband signals on corresponding at least two signal lines of the cable from the sensor to the measurement hub.

The at least two baseband signals are analog baseband signals. In one implementation, the measurement hub comprises a receiver and an analog-to-digital converter (ADC). In another implementation, the sensor comprises an analog-to-digital converter (ADC) and a serializer for transmitting serial digital data to said measurement hub.

Preferably, with either of the two implementations, the sensor further comprises more bandpass filters than envelope detectors, and a RF switch for selecting, for each envelope detector, a respective bandpass filter.

The system further comprises additional one or more sensors of different types for detecting the partial discharge by alternative methods other than electromagnetic sensing, and an analog switch for selecting one of said additional one or more sensors.

The sensor is further configured to generate a calibration voltage as a calibration output of the sensor, the calibration output being selectable by an analog switch.

The system is further configured to transmit a signal representing a maximum voltage span as the calibration output. The measurement hub further comprises:
a reference circuit generating a local reference voltage exceeding the calibration response received by the receiver responsive to said maximum voltage span transmitted by said sensor;
a digitally controlled reference divider for scaling said local reference voltage to match a response of the receiver when receiving said maximum voltage span as said calibration output, to produce a digitally scaled reference voltage;
a comparison means for comparing said digitally scaled reference voltage and said received calibration response; and
a second voltage scaling means configured to apply a second scaled replica of said digitally scaled reference voltage as a common mode voltage offset of said receiver.

The system may use one or more of the following sensors: Temperature sensor; Humidity sensor; Dust sensor; Condensation sensor; Audible sound sensor; Ultrasonic PD sensor; Pressure sensor; and Dew point sensor.

The system further comprises a built-in self-test module, proximate the sensor, the built-in self-test module being able to synthesize a UHF signature of the partial discharge under command of said measurement hub. The sensor is configured to report measurements before, during, and after an activation of said built-in self-test module. The measurement hub is configured to compare the measurements; and assess a health of said sensor based on deviations of said measurements.

In accordance with another aspect, the invention provides a method of operating a system for detecting a partial discharge. The method comprises:
(a) placing a sensor so as to receive ultra-high frequency (UHF) signals related to the partial discharge, the sensor comprising at least one antenna and at least two envelope detectors connected to at least one of said at least one antenna through respective bandpass filters;
(b) placing a measurement hub located so as to allow safe access and having a computational platform;
(c) interconnecting the sensor and the measurement hub by a cable;
wherein:
(d) the step (a) comprises deriving, by said at least one antenna, at least two UHF signals in two different frequency bands;
(e) the step (a) further comprises simultaneously detecting, by said at least two envelope detectors, said at least two UHF signals respectively, providing respective at least two baseband signals; and
(f) transmitting a facsimile of said at least two baseband signals on corresponding at least two signal lines of said cable from said sensor to said measurement hub.

The method further comprises a calibration procedure, performed after the step (c) and before the steps (d), the calibration procedure comprising:
(i) by the measurement hub, instructing the sensor to output a full-scale calibration signal;
(ii) at a receiver of the measurement hub, receiving the full-scale calibration signal, and presenting it to a comparator of the measurement hub;
(iii) by a computational platform of the measurement hub, adjusting a first scale factor of a reference voltage until the full-scale calibration signal and a scaled replica of the reference voltage are sufficiently equal; and
(iv) repeating the steps (i) to (iii) until an error between the full-scale calibration signal and the scaled replica of the reference voltage is within a predefined first tolerance.

The method further comprises performing the following steps by the measurement hub, after the step (c) and before the steps (d):
(i) instructing said sensor to output a half-scale calibration signal;
(ii) monitoring a response from an analog-to-digital converter of the measurement hub to said half-scale calibration signal; and
(iii) adjusting a second scale factor of a reference voltage until the half-scale calibration signal obtains a half-scale digital reading from an analog-to-digital (ADC) converter of said measurement hub; and
(iv) repeating the steps (i) to (iii) until said half-scale digital reading is within a predefined second tolerance.

The method further comprises a calibration procedure, performed after the step (c) and before the steps (d), the calibration procedure comprising:
(i) by the measurement hub, instructing the sensor to output a full-scale calibration signal;
(ii) at a receiver of the measurement hub, receiving the full-scale calibration signal, and presenting it to a comparator of the measurement hub;
(iii) by a computational platform of the measurement hub, adjusting a first scale factor of a reference voltage until the full-scale calibration signal and a scaled replica of the reference voltage are sufficiently equal;
   (iv) repeating the steps (i) to (iii) until an error between the full-scale calibration signal and the scaled replica of the reference voltage is within a predefined first tolerance;
(v) instructing said sensor to output a half-scale calibration signal;
(vi) monitoring a response from an analog-to-digital converter of the measurement hub to said half-scale calibration signal;
(vii) adjusting a second scale factor of a reference voltage until the half-scale calibration signal obtains a half-scale digital reading from an analog-to-digital (ADC) converter of said measurement hub;
(viii) repeating the steps (v) to (vii) until said half-scale digital reading is within a predefined second tolerance; and
(ix) repeating the steps (i) through (viii) until both the full-scale calibration signal and said half-scale digital reading are within said respective predefined first and second tolerances.

### The Method Further Comprises:

providing more bandpass filters than envelope detectors for said sensor, and a radio frequency switch for selecting a respective bandpass filter for each envelope detector;
prior to the step (c), by the measurement hub, performing the following steps:
   commanding said sensor to scan available bandpass filter responses by controlling a selection of frequency bands coupled to each envelope detector by respective RF switches;
   determining the average signal noise levels for each envelope detector; and
   selecting a bandpass filter response from each envelope detector to provide the lowest average signal noise level for each envelope detector, provided each frequency band is used in one detector only.

### The Method Further Comprises:

placing a built-in self-test module proximate to said sensor and connected to said measurement hub;
after the step (c), by the measurement hub, performing the following:
commanding said built-in self-test module to output a pattern of simulated partial discharge;
scanning available bandpass filter responses by controlling a selection of frequency bands coupled to each envelope detector by respective RF switches;
determining the most often recurring signal levels with said built-in self-test module idle and recurring signal levels with said built-in self-test module creating partial discharge signatures for each envelope detector; and
selecting a bandpass filter response from each envelope detector to provide the highest ratio of the recurring partial discharge signal ratio to the recurring idle signal level for each envelope detector, provided each frequency band is assigned to one detector only.

### The Method Further Comprising, by the Measurement Hub:

detecting said least two UHF signals in two different frequency bands;
correlating said two UHF signals to determine a confidence level that said two UHF signals are representative of the partial discharge;
otherwise, reporting unconfirmed partial discharge.

### The Method Further Comprises:

by said measurement hub, upon detecting the partial discharge, measuring the partial discharge by at least one alternate PD sensor using an alternative method other than a electromagnetic sensing; and
using results from said at least one alternate sensor to confirm a presence of the partial discharge.
   The Method Further Comprises the Following Steps, after the Step (c):
placing built-in self-test module proximate to said sensor and connected to said measurement hub;
by the measurement hub, commanding the built-in self-test module to output a pattern of simulated partial discharge;
measuring a response of the system for detecting a partial discharge to said simulated partial discharge; and
validating a proper functioning of the system for detecting a partial discharge based on the measured response.

Thus, an improved method and system for monitoring and detecting the partial discharge in electric power equipment, and a method of operating the system have been provided.

### BRIEF DESCRIPTION OF THE DRAWINGS

Embodiments of the present invention will be further described with reference to the accompanying exemplary drawings, in which:

FIG. 1 shows a prior art arrangement 100 showing a plurality of radio frequency front ends with a band select switch and a log detector; with only the antennas being located in one or more process areas.

FIG. 2 illustrates a process area and instrumentation compartments of a typical power asset with a smart sensor in the process area, a signal processing system in an instrumentation compartment, and a low frequency cable therebetween;

FIG. 3 shows a revision of FIG. 1 in accordance with the invention having a first receiver channel and a second receiver channel located in the process area;

FIG. 4 shows a block diagram 400 of a smart sensor for measuring PD of embodiments of the present invention; with all elements of two simultaneous receivers being located within a process area and a multi-channel cable between said smart sensor and an instrument;

FIG. 5A shows a measurement channel 500 as an improvement of 310 and 320 with DC calibration at mid-scale and maximum limits plus UHF and Ultrasonic PD measurement channels, the measurement channel being a more preferable subcircuit 201, 202 of FIG. 2;

FIG. 5B shows example waveforms, including a UHF envelope pulse 554, ultrasonic waveform 555, half scale calibration voltage 552, and full scale calibration voltage 553;

FIG. 6 shows digital control scheme 600 of FIG. 4, with additional sensors;

FIG. 7A shows an implementation for protection and matching circuit 700 for Ethernet cable embodiments for a first analog sensor signals from an envelope detector;

FIG. 7B shows an implementation for protection and matching circuit 700 for Ethernet cable embodiments for a second analog sensor signals from an envelope detector;

FIG. 7C shows an implementation for protection and matching circuit for Ethernet cable embodiments, with one of a clock or data signal and a ground or power return signal;

FIG. 7D shows an implementation for protection and matching circuit for Ethernet cable embodiments; with one of data or clock signal and a power signal;

FIG. 7E repeats an implementation for protection and matching circuit 700 for Ethernet cable embodiments for a first analog sensor signals from an envelope detector;

FIG. 7F repeats an implementation for protection and matching circuit 700 for Ethernet cable embodiments for a second analog sensor signals from an envelope detector;

FIG. 7G shows an implementation for protection and matching circuit for Ethernet cable embodiments; with a data and a clock signal sharing a twisted pair;

FIG. 7H shows an implementation for protection and matching circuit for Ethernet cable embodiments; with ground or power return sharing a twisted pair;

FIG. 8 shows a protective scheme 800 for electronics measuring conductivity and dielectric constant;

FIG. 9 shows a physical arrangement 900 of a four-antenna partial discharge system with connector and cable;

FIG. 10 shows a built-in self test (BIST) circuit 1000 for partial discharge within a partial discharge sensor, being part of a second device co-located in a process area with the sensor;

FIG. 11 shows a measurement hub 1100 with 4 BIST devices and 4 sensor inputs from PD and other sensors, the sensors and BIST devices being in process areas and the hub being in an instrumentation compartment;

FIG. 12 shows a partial discharge measurement hub 1200 with phase input for synchronizing partial discharge;

FIG. 13 shows a protective circuit 1300 for the hub end of a cable;

FIG. 14 shows a receiving circuit 1400 for the analog signal at the hub end of a cable having active trimming;

FIG. 15 shows a transmitting circuit 1500 for the analog signal at the sensor end of a cable having active trimming;

FIG. 16 shows a transmitting circuit 1600 sending digitized data for improved noise immunity;

FIG. 17 shows a partial discharge system 1700 with measurement system integrated to smart sensor;

FIG. 18 presents an overview of the system for detecting a partial discharge of the embodiments of the present invention; and

FIG. 19 presents a block diagram 1800 of a measurement hub having analog signals, shape correlation, coincidence filter, and synchronicity filter to provide validated PD events.

### DETAILED DESCRIPTION OF EMBODIMENTS

Responsive to the needs of a comprehensive system, there are disclosed the following specific sensor implementations and methods of construction.

Embodiments of present invention alter the division of functions between the process area and the instrumentation compartment to avoid the known shortcomings of the prior art without incurring the low reliability and safety of placing the entire partial discharge monitoring system into the process area.

Systems measuring PD external to or on the outer surfaces of electrical power assets are known to suffer external radio interference. Systems completely located within the high voltage compartments of switchgear pose safety and reliability concerns. Systems placing antennas internal to the asset with the electronics external to the asset have enjoyed acceptance but have signal degradation and common mode interference due to the lengthy radio frequency (RF) cables between the antenna and the electronics.

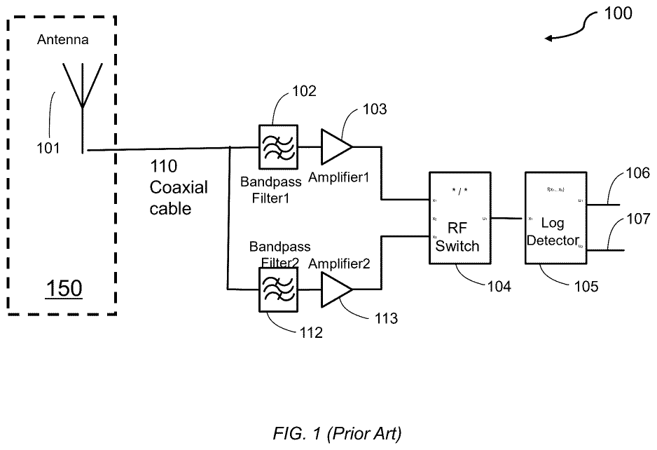

FIG. 1 shows a block diagram of subcircuit 100 of the prior art in which antenna 101 located within process area 150 transmits UHF signals on coaxial cable 110 that feeds two filters 102, 112, two LNAs 103, 113, and an RF switch 104 before being converted to a baseband signal by a logarithmic envelope detector 105 outputting differential signals 106, 107.

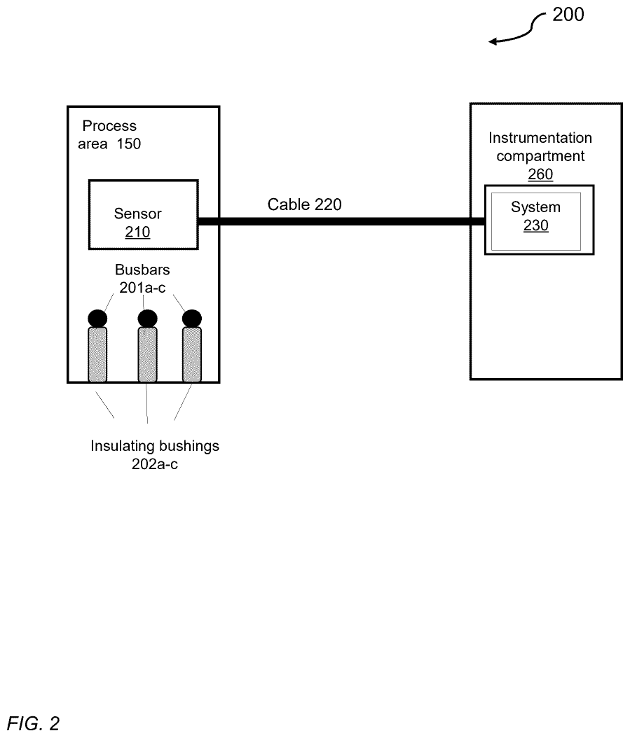

FIG. 2 shows an embodiment 200 with a process area 150 and an instrumentation compartment 260. The process area includes medium voltage busbars 201a-c supported by insulating bushings 202a-c. It also contains at least one sensor 210 connected to a system in the instrumentation compartment by a cable 220. In the prior art, the cable would carry UHF radio frequency signals, and the sensor would comprise a passive sensor, such as a single, broadband antenna. In related applications for monitoring temperature, there might also be passive wireless sensors situated on the bus bars. In the present invention signal processing through to envelope detection 105 is provided within the sensor, the cable carries lower frequency signals at a high signal to noise ratio, and the remainder of the system 230 continues to reside in instrumentation compartment 260.

The present invention deviates from the prior art and places a limited amount of high reliability electronics within a suite of sensors located within the process area while retaining the high complexity electronics external to the electrical power process for ease of maintenance and safety. By placing at least the filter, gain, and envelope detection circuitry integrated into process area 150 with at least one antenna 101, the bandwidth, loss, and noise performance requirements of the cable are reduced and the signal quality of the overall system is enhanced.

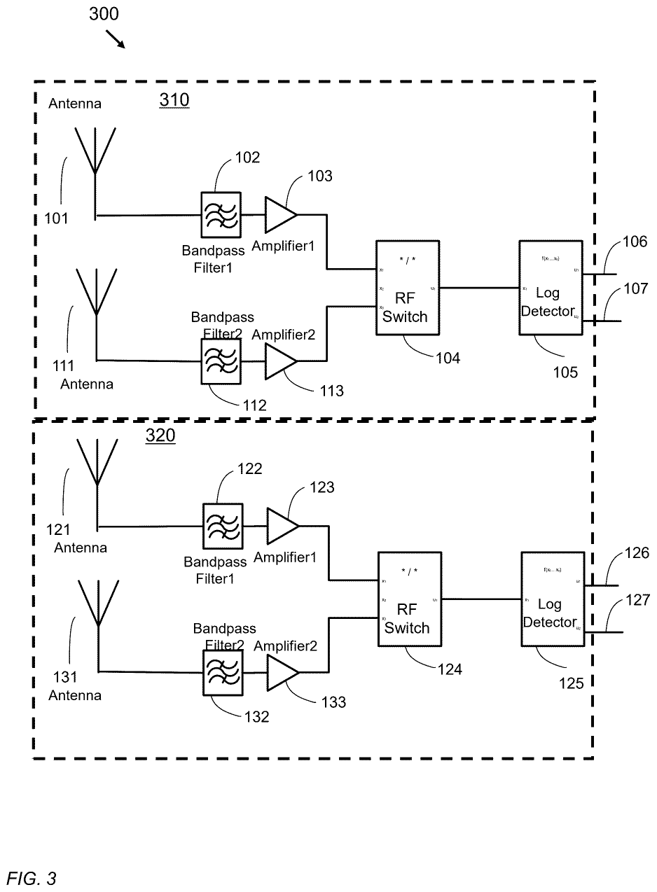

FIG. 3 shows a subcircuit 300 having two radio frequency front ends 310 and 320, also referred to as receivers. A first front end 310 has two antennas 101,111, two filters 102, 112, two amplifiers 103, 113, a band select switch 104, and a logarithmic envelope detector 105. A second front end 320 has two antennas 121, 131, two filters 122, 132, two amplifiers 123, 133, a band select switch 124, and a logarithmic envelope detector 125. Under external control switches 104 and 124 select the bandpass filter providing the best signal to noise performance, optimizing the output signals 106, 107 and 126, 127.

In a preferred embodiment, antennas are integrated to the smart sensor and are implemented either in the copper pattern of the printed circuit board (PCB) or by chip antennas in close electrical proximity to the RF signal chain. This eliminates coaxial cable 110 and the variability and noise issues that it introduces. In one alternative embodiment, the LNA 103 is placed between antenna 101 and bandpass filter 102 to minimize the noise figure of the system. This has the advantage of insulating the antenna and bandpass filter from impedance mismatch, which could be problematic for some filter technologies. It has the disadvantage that the LNA could be overdriven by large interfering signals. In other alternative embodiments, the LNA is placed between the bandpass filter 102 and RF switch 104 as shown in FIG. 1 and FIG. 3. This has the advantage of protecting the low noise amplifier from strong interfering signals. In still other alternatives the amplifier may be placed between the RF switch 104 and log detector 105, reducing the parts count and cost while increasing reliability but also further increasing the noise level.

In at least some embodiments, a plurality of radio filters and optional amplifiers, illustrated by bandpass filters 112, 132, LNAs 113, 133, are present and a desired first and second frequency band is selected by RF switches 104 and 124.

The number of selectable frequency bands in front ends 310 and 320 is a matter of technical choice and the number may be different for the individual subcircuits. The use of more frequency bands allows known radio frequency interference to be avoided more easily but incurs more cost and complexity. The number of subcircuits is also a matter of technical choice. The most preferred implementation uses two bands per subcircuit and two subcircuits.

Log detector positive outputs 106, 126 is provided as a low frequency electrical signal. In some embodiments of the present invention, complementary outputs 107, 127 are provided, allowing differential transmission of the logarithmic facsimile of the RF signal selected by switches 104 and 124. Linear envelope detectors are employed in some embodiments and envelope detectors with any monotonic detection function may be used.

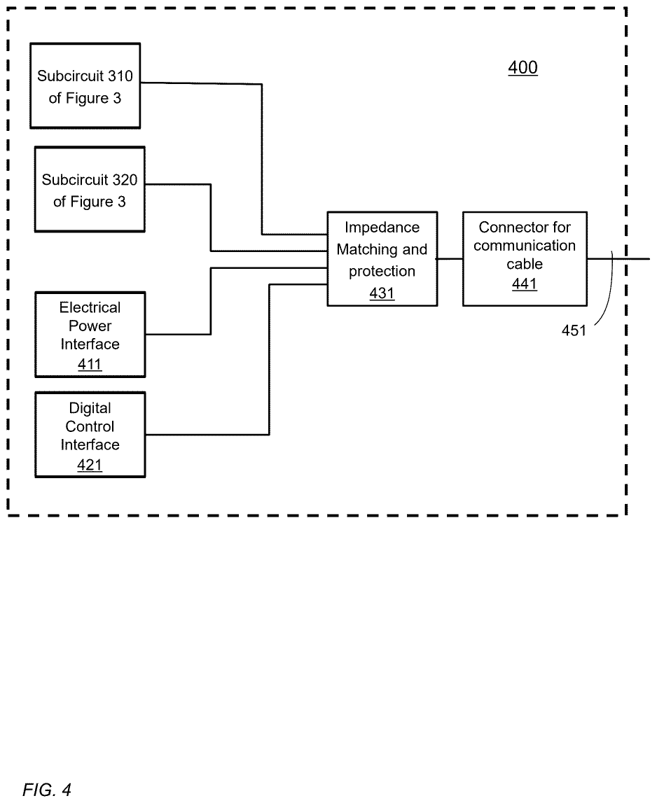

FIG. 4 shows a block diagram 400 of a smart sensor for measuring PD according to aspects of the present invention. The smart sensor comprises at least two subcircuits 310 and 320 similar to those described in FIG. 3, along with electrical power interface 411 and digital control interface 421. Subcircuits, power, and control signals are protected and impedance matched 431 as discussed later and provided at a suitable connector 441 for communication by cable 451 to a host system for signal processing in a less hazardous and more accessible instrumentation compartment.

Electrical power interface 411 accepts power for the circuitry and conditions it for electromagnetic compatibility and immunity (EMC and EMI). Control signals may use a variety of available or future interfaces. I2C and other two-wire interfaces are popular and convenient, as are RS485 and related protocols. The digital control interface controls frequency selection and other self-calibration functions to be controlled by a two-wire port expander providing the requisite control signals latched to wires from data on the control interface. as the control interface may also connect additional sensors discussed later.

Impedance matching and protection circuit 431 is designed to protect the smart sensor from electromagnetic transient coming from the cable and to protect the cable and attached systems from electromagnetic transient coming from the smart sensor. Protection should include over-voltage transient protection and common mode radio frequency interference protection, at the least. An exemplary construction of a smart antenna comprises a plastic housing with galvanic isolation of the electronic circuit and antennas from the switchgear. In this case, it is reasonably assumed that the dielectric material protects the circuit from the electrical process and that simple series protection is suitable. Common mode chokes, Zener diodes, and transient blocking units offer functional protection to the smart antenna and to the cable itself. An optional gas discharge tube or similar protective device could clamp circuit common node to protective earth in extreme conditions.

In addition to providing the protection required for functional and safety aspects of electromagnetic compatibility (EMC), this circuit should also match the circuit impedance to the cable impedance for the partial discharge analog baseband signals of the envelope detectors. Series resistance is added in the signal paths of subcircuits 310 and 320 to match the typical 100 Ohm impedance of the twisted pairs to the protected impedance of the log detector. To maintain a 1% accuracy over varying phase shifts of an interfering reflected signal on a cable, the reflection coefficient at each end of the cable should be less than 10% which allows the termination impedance to have a 20% error relative to the cable impedance. This is consistent with the typical tolerances of electronic fuses suitable for the protection function.

Connector 441 and cable 451 should also carry a two-wire interface such as I2C or RS485. This signal channel is employed for digital control of subcircuits 310 and 320 as well as other sensor electronics.

Two pairs of wires carry power and digital controls while the remaining pairs carry differential logarithmic facsimiles of the filtered and amplifier radio frequency signals. The plurality of radio frequency front ends enables the “coincidence filter” as described in detail in the U.S. application Ser. No. 19/197,943 (OSN-001-US) cited above.

The number of parallel subcircuits and thus the number of selected bands for simultaneous analysis is also a matter of technical choice. The most preferred implementation allows the use of pervasively available Ethernet cables and with four cable pairs (2 analog envelope detector signals, power, and control) as seen in FIG. 4. It further uses two bands per subcircuit, allowing a low complexity and low parts count while implementing the “coincidence filter” of “Multi-Band UHF Detection and Identification of Partial Discharge” and allowing noise avoidance within a lower frequency and upper frequency receiver.

In other words, FIG. 4, blocks or subcircuits 310 and 320 comprise at least two UHF sensors with different filter passbands, as shown in FIG. 3. These two sensors could be correlated to ignore signals that are not coincident in both frequencies at the same time with similar amplitudes. Block 411 receives power from the cable and block 421 receives control signals from the cable to configure 310 and 320. Block 431 implements protection of 310, 320, 411, and 421 from hazards in the process area, providing the required long-term reliability and safety of electric power systems. Connector 441 couples to cable set 451 that brings signals to the remainder of the system. This partition of functions allows the integration of critical aspects of the circuit with improved sensitivity and reproducibility.

In addition to radio frequency energy, PD is also known to emit acoustic energy in the audible and ultrasonic frequency ranges. MEMS microphones exist with high sensitivity, high reliability, and broad high frequency responses. Employing such a microphone into a stand-alone PD detector is known in the prior art. Filtering the response of such a microphone into, for example, signals below 20 KHz and signals above 20 KHz allows the novel coincidence methods of the present invention. Integrating such a sensor into a UHF sensor allows automated confirmatory measurements. PD that occurs on the surface is known to emit Ultraviolet energy and UV energy may also be used to confirm certain classes of PD.

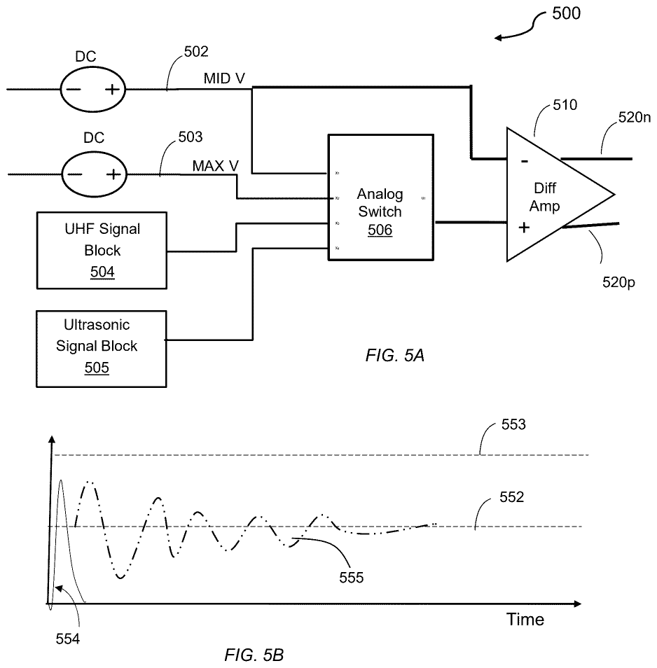

FIG. 5A shows a measurement channel 500 being a more preferred embodiment of subcircuits 310 and 320. In addition to said UHF signal block 504 of, for example, FIG. 3, DC calibration at mid-scale 502 and maximum 503 levels are included. Ultrasonic PD measurement channels 505 or Ultraviolet PD measurement channels are also included. The DC calibration voltages enable cable and protection circuitry calibration for an additional level of built-in self-calibration in which an analog switch 506 multiplexes a mid-scale differential DC voltage 502, a maximum differential DC voltage 503, the positive output of a log detector subcircuit 504, and the ultrasonic signal block 505 as an expanded implementation of subcircuits 310 and 320 of FIG. 3 or FIG. 4. In practical applications, voltages 502 and 503 and signals 504 and 505 are single ended and the differential signal is created after analog switch 506 by a differential amplifier 510 subtracting midscale voltage 502 for reduced parts count and complexity. If the signal scale is judiciously chosen to range from 0 to 2.048V, by way of non-limiting example, then the MAX V would be 2.048 and the MID V would be 1.024. The differential amplifier output would be a scaled replica of −1.024˜+1.024V with the amplifier gain being the scale factor. Selecting MAX V would output a full scale positive differential voltage and outputting MID V would output zero differential voltage. Having a control mode that outputs 0V differential when not in use minimizes current consumption of the sensor.

Thus, FIG. 5A shows an alternate embodiment of 310 and 320 in which 504 comprises a UHF detection block, 505 comprises an alternate detection, for example, ultrasonic or ultraviolet, and 502 and 503 provide a first and a second calibration voltage. Analog switch 506 multiplexes one of the four selected signals and provides an output via differential amplifier 510 being the difference of 520p and 520n. Inclusion of alternate sensor allows confirmation of a detected partial discharge condition. Inclusion of one or both DC voltages allows the baseband signal path to be calibrated. Calibration is necessary since the aforementioned +/−10% variation in matching impedance due to tolerances of the protective elements can result in a +/−10% variation in the voltage measured at a perfect load with no cable resistance.

FIG. 5B illustrates the relationship of midscale voltage 552, full scale voltage 553, UHF envelope pulse 554, and ultrasonic waveform 555.

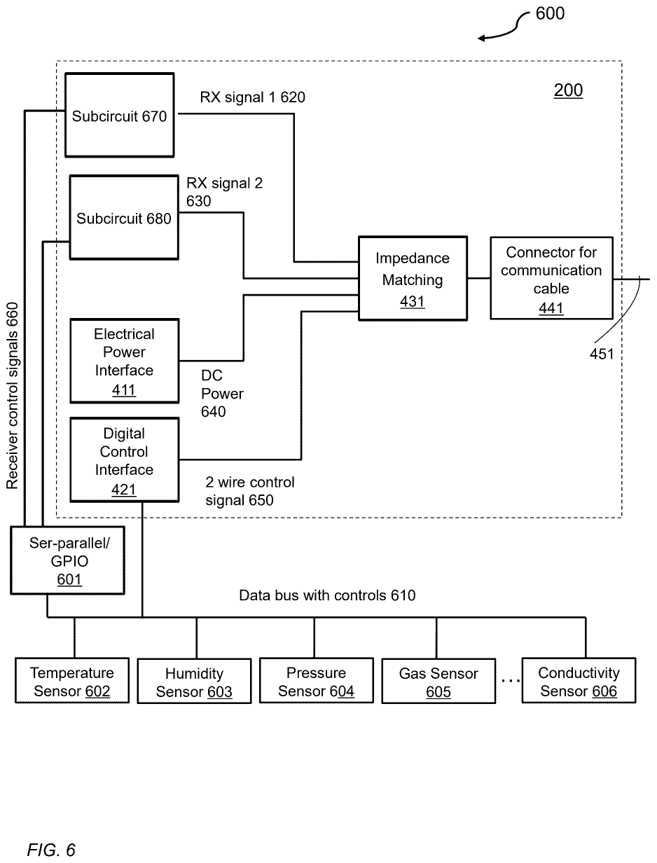

FIG. 6 shows digital control scheme 600 of FIG. 4, with additional sensors. FIG. 6 shows that the control signals can control not only blocks/sensors 670 and 680 using serial to parallel General Purpose Input/Output (GPIO) latch 610 to drive control signals 660 controlling a first 670 and a second 680 detection subcircuit, but also additional sensors 602-606 that might be desirable and are required to be physically located in the process area on data bus with controls 610. These sensors might include one or more of the following: ambient temperature 602, humidity 603, dew point, pressure 604, gas sensors 605, surface contamination, airborne particulates, conductivity 606, dielectric constant, and the like. Sensor 600 having digital control Interface 421 implements signal bus 610 with controlled devices. In an exemplary case the interface 421 is an I2C bus redriver that may optionally include isolation or level translation and bus 610 is an I2C bus. Control signal latch 601 could be an I2C port expander providing parallel GPIO latched from the serial data 610 to determine the selection of calibration or measurement configuration of partial discharge measurement channels 670 and 680. Sensors 603-606 could be any of a variety of auxiliary sensors for one or more of humidity, ambient temperature, dew point, pressure, combustible or corrosive gases, ultraviolet (UV) photodetectors, surface contaminants, conductivity, dielectric constant, airborne particulates, and the like. In another example, 421 is an RS485 to I2C conversion circuit. RS485 has the advantage of symmetric differential signaling on a single pair and therefore has better noise immunity. The tradeoff is the added complexity of converting RS485 to a protocol commonly used by chip-scale sensors. Alternate signals protocols include by nonlimiting example Controlled Area Network (CAN), Low-Voltage Differential Signaling (LVDS), and the like. I2C is widely supported by the desired sensors but it is generally difficult to protect over long cables. Differential peer to peer protocols are easier to protect but add complexity in the sensor interfaces. For embodiments employing four pair cables it is convenient to use commercial Ethernet cables. T-568 A and T-568B pinouts differ in that the pair on pins 1 and 2 is swapped with the pair on pins 3 and 6. T-568 A is the predominant and any pair to pin assignment is acceptable when both ends of a cable use the same pinout. So-called cross-over cables have T-568 A at one end and T-568B on the other end. Placing power on pins 4 and 5 preserves their location in a cross-over cable and, with reverse power protection in block 431 or 411, protects from accidental reverse order of pins. Placing the digital control signals on pins 7 and 8 preserves their position on a crossover cable. An accidental reverse wiring would swap them for a signal line which would be non-functional. Block 231 should provide electrical protection for such wiring errors. Placing the analog signals of blocks 201 and 202 on pins 1 and 2 and pins 3 and 6 will swap the channels but will preserve their functionality if a cross-over cable is employed.

In embodiments using standard Ethernet cables, a controller could implement a method of discovery and calibration that first verified digital communications to verify power and controls are properly wired. Second the system would enable one of blocks 670 or 680 and detect upon which pair that block is electrically connected. Third, the blocks would be configured for each supported calibration configuration before normal operation.

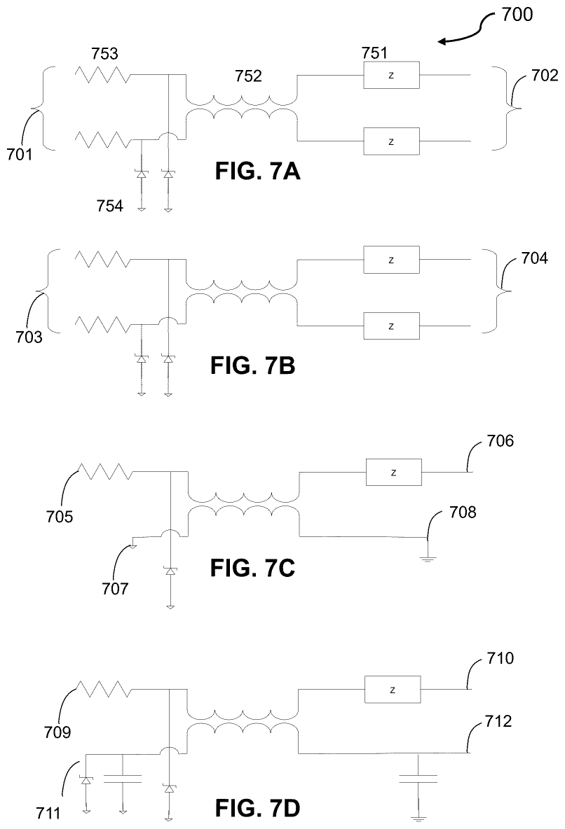

FIGS. 7A, 7B, 7C, 7D, 7E, 7F, 7G, and 7H disclose protection schemes of block 431. Elements Z 751 et al. are fast electronic fuses that will pass normal signals but can block the impulses associated with surge and electrical fast transients (EFT) and are the critical safety aspect of the protection, attaching to the cable. Common mode choke filters 752 et al. help to reduce common mode interference on the cable from interrupting the proper operation of the sensor. Transient absorbers 754 et al. clamp any surge, EFT, or electrostatic discharge to safe levels. Finally, series resistors 753 et al. provide the balance of the source impedance of the cable for data and signal lines. The resistor values are selected to nominally obtain 50 Ohms per channel on at least the signal pairs; however, the tolerance part to part on the electronic fuses is considerable. The variability is not too large to properly reduce reflections but is too large for proper signal amplitude consistency.

FIGS. 7A, 7B, 7C, 7D, 7E, 7F, 7G and 7H show alternative protection and matching circuits for Ethernet cable embodiments. Circuits A-D correspond to four pairs in which two pairs are a first and a second sensor signal, one of a data or clock is paired with one of a power or power return and the other signal or clock is paired with the other power or ground. This set has better isolation of data and clock lines but has worse common mode isolation. Circuits E-H correspond to cases where control signals are paired together, and power signals are paired together. This set has better common mode rejection but can present signal to clock crosstalk in unbalanced protocols like I2C or SPI. It is better suited for RS485, CAN, or the like but can be used for asymmetric protocols as well.

In embodiments using Ethernet cables or other shielded twisted pairs, the protection of FIGS. 7A, 7B, 7E, and 7F presents a de minimus protection for the analog differential signals. Elements ‘Z’ 751 et al. are fast series ‘fuses’ known as transient blocking units (TBUs). Such components trip to a high impedance and block hundreds of volts from the line side (even numbered pins or pairs) to the protected side when the current exceeds a trigger current. In cases where the line transient voltage could exceed the TBU voltage, a gas discharge tube or metal oxide varistor could also be placed on the line side.

In FIGS. 7A, 7B, 7E, and 7F, common mode chokes 752 et al. provide a low impedance to differential signals and a high impedance to common mode interference. Resistors 753 et al. optionally match the line impedance to the signal source impedance, at least for analog ports 701, 703, 721, and 723. For Ethernet lines the individual resistor would be the remainder of 5002 less the line resistance of the common mode choke and the TBU while the analog signal source would be designed to differentially drive 20052 representing the series source match and cable impedance. The Zener diodes 754 et al. draw little current at normal signal voltages but draw significant current under an overvoltage transient, tripping TBUs.

A first embodiment 700 shows one digital control line 705, 706, for example, the data line of I2C, common mode filtered with ground 707, 708 in FIG. 7C, and the other 709, 710, for example, the clock line of I2C, common mode filtered with power 711, 712 in FIG. 7D. The nominal resistance of the TBUs 751 et al. and line matching resistors 753 et al. would be too high for the power or ground path and only the common mode choke 752 et al. is provided. Not properly terminating the lines for power and for low speed data is acceptable as reflections are negligible at the frequencies involved.

Another embodiment 720 pairs the two digital control lines 725, 726 and 727, 728 together through TBUs 751 et al. and common mode filters 752 et al. as seen in FIG. 7G, which is more appropriate to differential signaling. Matching resistors 753 et al. are optional and depend on the protocol.

In FIG. 7H embodiment 720 further pairs power 731, 732 and power return or ground 729, 730 with only common mode choke 752 et al. and Zener diode 754 et al.

For signals like I2C, where the clock transitions and data transitions are at quadrature, the 700 embodiment reduces data noise on clock transitions that could occur due to high capacitance of long lines. On the other hand, the arrangement 720 better blocks common mode noise pair by pair. Differential signaling such as LVDS, RS485, or CAN would prefer to use the embodiment of 720 while I2C might use either case depending on the relative concern of self-interference vs. externally induced EMI.

Auxiliary sensors are generally known in the prior art. Many vendors sell humidity, temperature, dew point MEMS sensors, pressure and temperature sensors, UV photosensors, gas sensors, and particulate sensors. Humidity and temperature sensors are desirable for air insulated assets. Pressure and temperature sensors are desirable for compressed air or SF6 gas insulated assets. Conductivity and dielectric sensors are desirable for oil filled assets. Particulate sensors are desirable for air insulated assets. UV photodetectors are broadly suitable for detecting UV emissions from surface discharges and corona. Gas sensors and chemical sensors in general are broadly suited to detecting corrosive gases or gases that are signatures of insulation damage. These sensors are readily integrated.

The present invention also discloses integration and protection of a system for the measurement of surface contaminants and their relative risk of electrical flashover due to reduction of surface comparative tracking index (CTI), utilizing techniques from US2012197566 A1 “INSTRUMENTATION FOR MEASUREMENT OF CAPACITANCE AND RESISTANCE AT HIGH RESISTANCE VALUES WITH IMPROVED DYNAMIC RANGE AND METHOD FOR USING SAME”, which is incorporated herein by reference. The prior art system 806 employs digital to analog converter (DAC) with polarity inverter 865 through series protective element 805 to drive a first electrical connection of an interdigital electrode of capacitor 801. Gas discharge tube 803 provides overvoltage protection. Output electrode of 801 is passed through series protection 804 to integrator 806. Comparator 862 detects zero crossings and comparator 864 detects threshold crossings set by DAC and inverter 864. Such a system could be implemented with an inter-digital electrode array on a Kapton flex circuit, said flex circuit entering the plastic housing of the smart antenna and coupling to suitable protection circuitry within the sensor, allowing capacitor 801 and guard ring 802 to be located outside the sensor and measurement circuit 806 with protection 803-805 located within the sensor. The protected signals would then couple to the measurement circuit and communicate with the host as an I2C slave or similar digitally controlled device on the control signal wires 610 of the smart sensor 600. The arrangement could monitor conductivity and dielectric constant in oil-filled assets or measure conductance and capacitance changes from dust and humidity in air with different firmware.

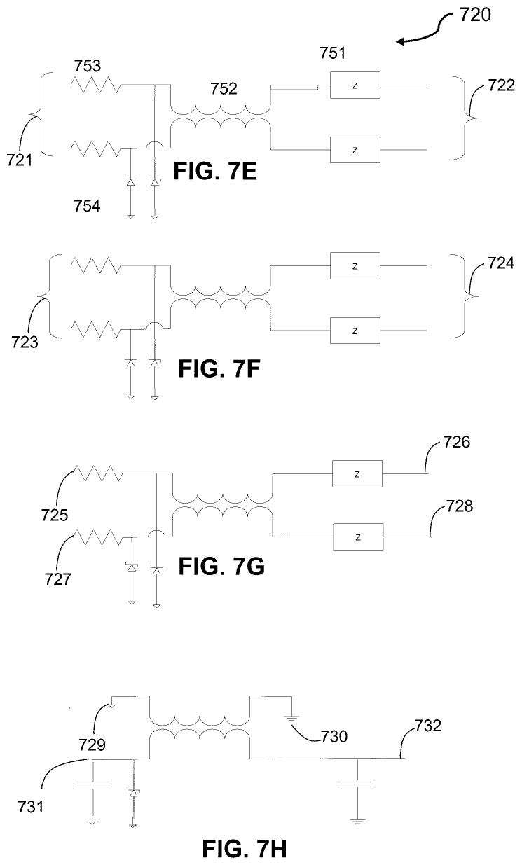

FIG. 8 shows a protective scheme 800 for the electronics. Namely, FIG. 8 shows a modification of US2012197566 A1 cited above in which sensor comprises inter-digital electrodes (IDE) 801 with guard electrode 802 connected to protective earth spaced so as to minimize capacitance from either the input or output of electrodes to protective earth (PE) relative to the capacitance between electrodes. Optional surge arrestor 803 further protects against overvoltage transients. Series resistors 804 and 805 are small compared to the measurement range of the system. More preferably resistors 804 and 805 comprise transient blocking units (TBUs) with optional Zener diode clamps (not shown). The remainder of circuit 806 is as described in US2012197566 A1, incorporated herein by reference.

Physically disposing the IDE and guard electrode on an exposed surface of the smart sensor allows it to be wetted by surrounding fluid media or to be polluted with particulates. In either case, changes in the fluid media or an increase in the amount and moisture content of particulates will change the conductance and capacitance of IDE. In the present application, the conductance of the particulates or insulating oil should be very low and the optional series resistors may be relatively large without significant loss of accuracy. These resistors and optional Zener diode barriers and the high voltage transient clamp protect the driving polarity inverter and receiving charge integrator from overvoltage transients in the system.

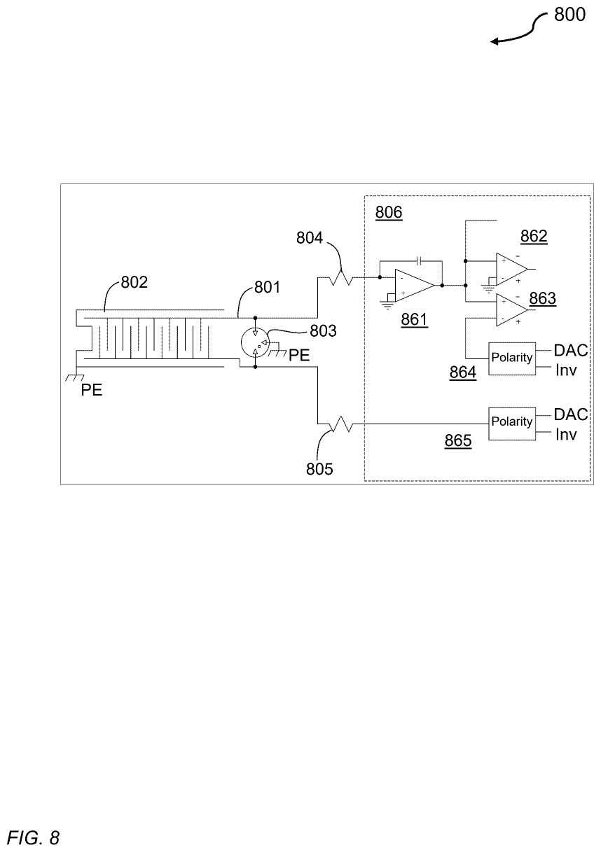

FIG. 9 shows a physical arrangement of a four-antenna partial discharge system 900. The system includes a circuit board 910 with four electrically small antennas 911, 912, 913, and 914 arranged around the periphery of said circuit board with said circuit board supported by a height 921 over the supporting ground plane 920. The arrangement around the outer periphery of the circuit board allows antenna elements to be separated from conductive elements of the measurement portion 915 of circuit board 910 and from one another. Electrically small antennas are used in some embodiments because they are small and because they are inherently narrow bandwidth, adding to the rejection of interfering signals. An alternate embodiment uses a single broadband antenna on PCB 910 and places measurement electronics 915 close to ground plane 920. In either case, measurement electronics 915 couple to cable connector 441 and cable 451.

The structural support of the circuit board over the supporting metal enclosure of the switchgear provides suitable separation of planar antenna elements from the parallel metal.

Typically, a radio wave from an insulation failure event would arrive roughly perpendicular to the circuit board and the antenna would convert a portion of the wave energy to an electrical signal. The remainder of the wave would pass the antenna, reflect from the metal wall with an opposing polarity, and induce another, inverted signal from the antenna with a phase shift dependent on the frequency and the distance. When the distance is ⅛^{th} of a wavelength or less or ⅜^{th} or more, the reflected wave decreases the magnitude of the received signal while from ⅛^{th} to ⅜^{th} the received signal is increased by the reflected wave. There is a tradeoff at lower frequencies between sufficient separation 921 and maintaining a safe distance of assembly 900 from high voltage conductors of the electrical equipment.

Distance 921 may be physically reduced by using high dielectric materials, high permeability materials, or electromagnetic absorber materials where lower physical height is required.

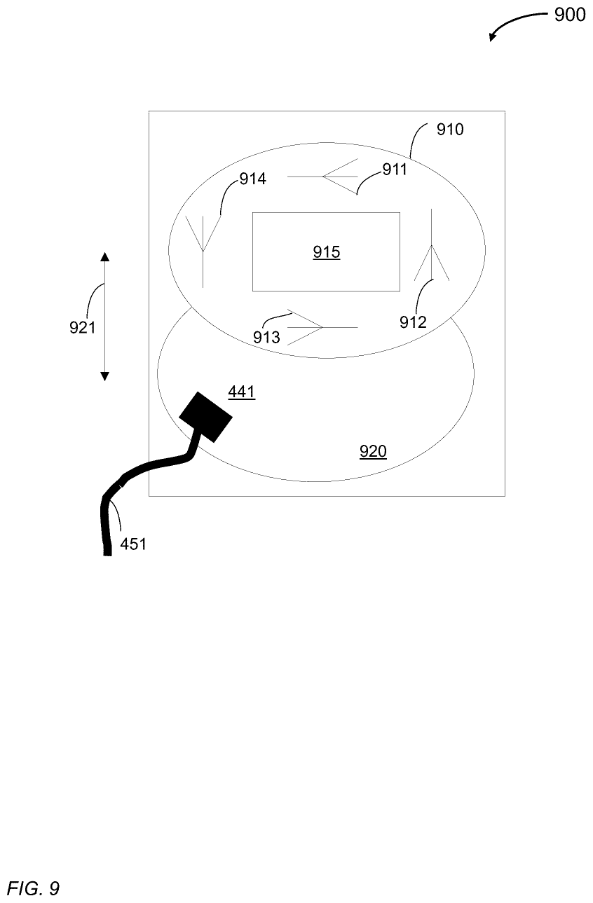

FIG. 10 illustrates a circuit 1000 that can create individual partial discharge events within a gas discharge tube 1010 with reproducible amplitudes. Placement of such built-in self-test (BIST) generator near a smart sensor allows periodic injection of a known partial discharge signal to validate proper functioning of the sensors. The indicated circuit is an improvement to U.S. Pat. No. 11,181,570B2 “Partial discharge synthesizer discloses a method for creating reproducible level of PD” incorporated herein by reference. BIST circuit 1000 of the present invention comprises low voltage power 1020 and control Metal-Oxide-Semiconductor Field-Effect Transistor (MOSFET) 1030, flyback transformer 1040, rectifier and integrator 1050, and discharge generator 1010. Raising control line CTRL causes MOSFET 1030 to conduct and charges flyback transformer 1040. Lowering control line causes the flyback to discharge. Rectifier and integrator 1050 produce a smooth, broad pulse from the fast spike of the flyback transformer.

Upon VCAP reaching a sufficient voltage, gas discharge tube 1010 sparks and the charge on the external capacitor and the internal capacitance of 1010 is discharged rapidly in an electrical arc with sub-nanosecond edges and controlled amplitude. For example, for a breakdown voltage of 300V and a capacitance of 1 pF total, the discharge is 300 pC.

In some embodiments said BIST circuit could be integrated into a smart sensor. In other embodiments it could be connected to an output connector on a smart sensor or cabled independently from a hub and located at a reference point within the system.

FIG. 10 shows a number of sensors on a number of cables with the sensors 1011, 1021, 1031, and 1041 proximate validation sources 1012, 1022, 1032, and 1042. Sensor 1041 further details contaminant sensor 1043 from FIG. 7 and an ambient temperature and humidity sensor 1044 in addition to the basic electronics of the partial discharge sensor 1045.

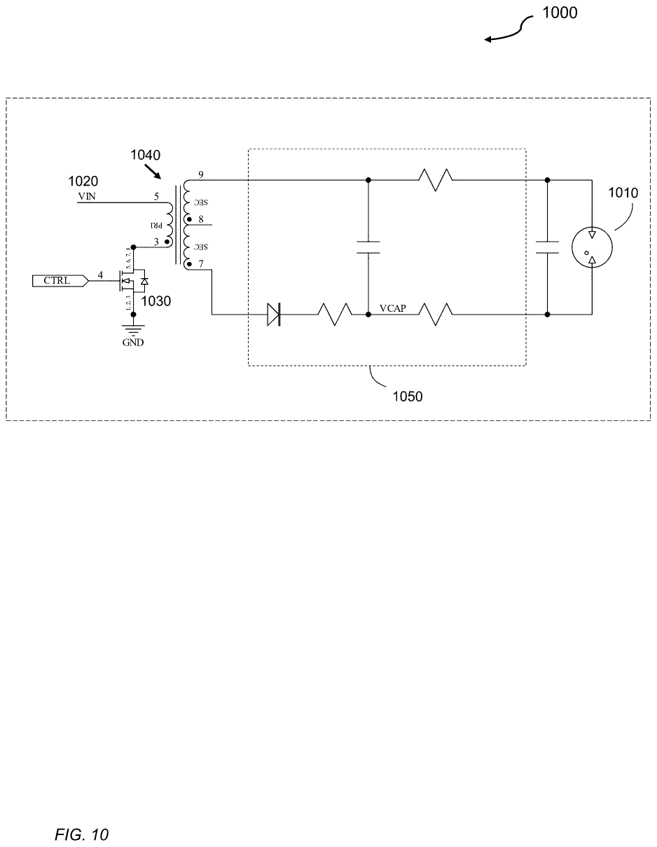

FIG. 11 shows a measurement system 1100 with sensor inputs from PD, Ambient Temp, Humidity, Dust, etc. FIG. 11 shows a control hub 1101 connected by Ethernet cables to smart PD sensors 1111, 1121, 1131, and 1141. Said hub is further connected to external BIST devices 1112, 1122, 1132, 1142. Smart PD sensor 1141 is further illustrated in detail to comprise a surface contaminant (dust and condensation) sensor 1143 and an ambient temperature and humidity sensor 1144 in addition to the partial discharge measurement electronics 1145. Hub 1101 communicates over the control signal pairs to configure calibration and measurements and to read data.

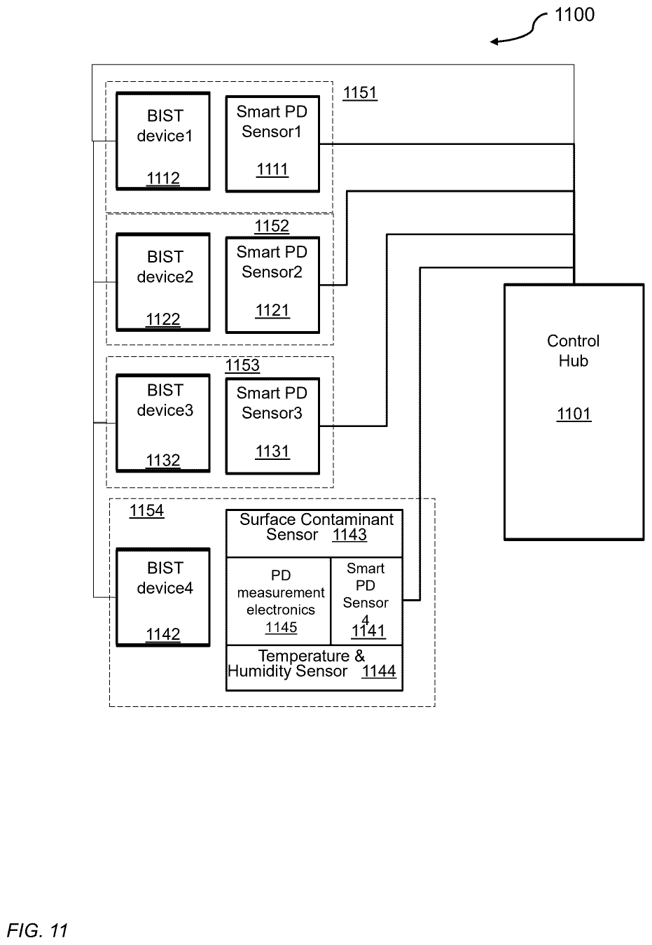

FIG. 12 shows a partial discharge measurement hub 1201 with phase input for synchronizing partial discharge from AC power source 1202. FIG. 12 shows a hub 1201 connected to an AC power distribution system 1202 with hub comprising protective current limiting and voltage limiting interface 1211, local DC voltage regulator 1212, zero crossing detector 1213, and optoisolator 1214. Voltage and current limiting protective circuit may comprise, by nonlimiting example, series resistors and shunt Zener diodes. The protection for the local DC voltage regulator may also comprise a diode rectifier. Voltage regulator may comprise by nonlimiting example additional series resistance and Zener diode voltage regulation. Zero crossing detector comprises by nonlimiting example a comparator comparing the current and voltage limited AC signals and a rising edge detector providing a controlled width pulse to an optoisolator on the positive going zero crossing of the AC waveform.

Hub 1201 further comprises a phase locked loop incorporating VCO 1220 with control signals to raise 1230 or lower 1231 the divided VCO frequency 1232, said divided VCO frequency used to compare to said AC phase while the internal VCO frequency is used to create internal clocks for the digital signal processing such that the processing is synchronized with the power frequency. In exemplary embodiments the VCO is on the order of 2\hat{ }19 to 2\hat{ }21 times the AC power frequency, giving on the order of 25 to 120 M samples per second clocking to analog to digital converters

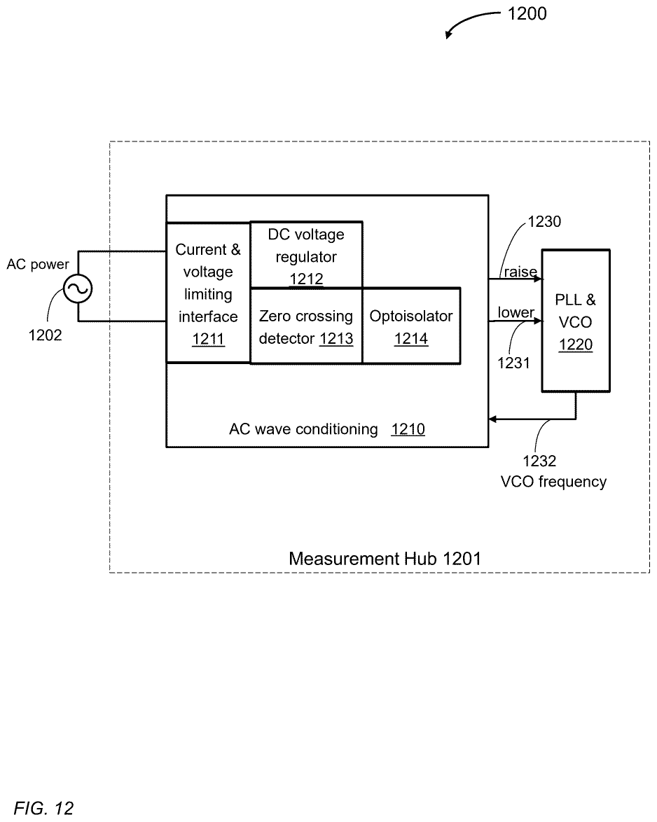

FIG. 13 shows a protective circuit 1300 for the hub end of a cable. Primary protection from gas discharge tube 1310 limits overvoltage transients. Resistors 1311p, 1311n, and 1311diff provide a terminating resistance for the differential wires, for example, totaling 100 Ohms for Ethernet cable. By taking the divided signal from 1311diff, the received signal is obtained with the ratio of 1311diff/(1311p+1311n+1311diff) optionally providing attenuation for signal amplitude control. Fuses 1320 are current limiting protection, ideally being semiconductor fuses such as transient blocking units (TBUs). Common mode choke 1330 blocks common mode noise while passing differential signals. Zener diodes 1340p and 1340n clamp overvoltage conditions and trigger fuses to isolate the receiver from overvoltage transients. Further current limiting protection of the small residual over-voltages are obtained from resistors 1350p and 1350n. Resistor divider scales the received signal and sets a reproducible load resistance on the cable. The division ratio allows for the proper total gain to enable an automated calibration feature. Placing the electronic fuses behind the resistive match allows the receiver load impedance to be independent of part-to-part variations of the electronic fuses. Multiple sensor channels are optionally multiplexed and fed to the receiver of FIG. 13.

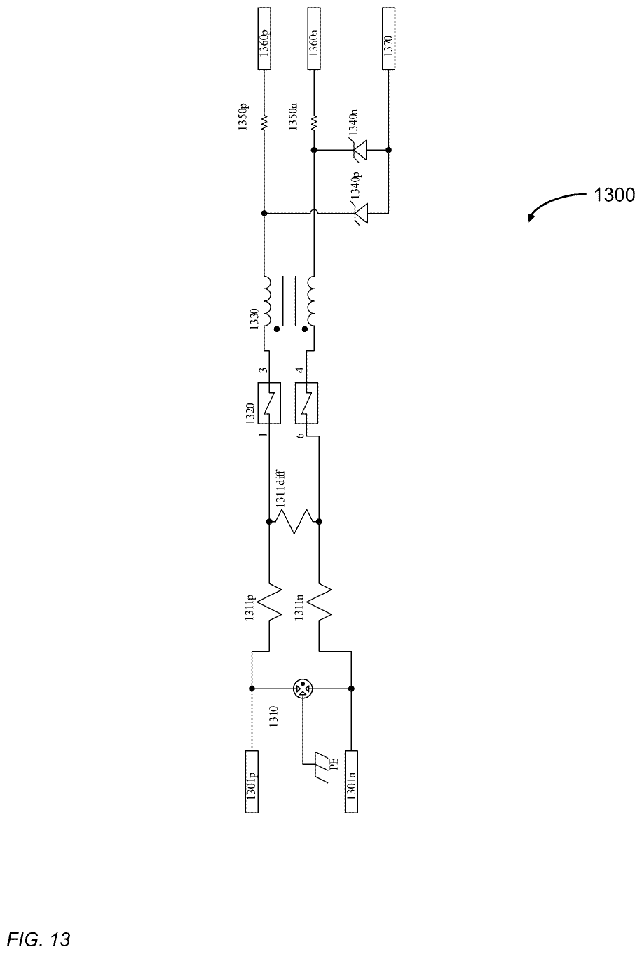

FIG. 14 shows a receiving circuit 1400 for the analog signal at the hub end of a cable having active trimming. Differential signal 1451, 1452 spanning +/−Vₘₐₓ is obtained from a protective circuit such as the circuit of FIG. 13, which, in turn, receives a differential signal from signal block 500 through protective block 700a.

Differential receiver 1401 provides receiver output signal 1454=A*(1452−1451+1453). Gain A is determined by resistors 1403, 1402, optionally adjusted by the parallel resistance of programmable potentiometer 1404 under control 1457 of a controlling system. Adjustment 1404 is optional and used to adjust significant gain errors of the system. Typical operational amplifiers have the best stability at a gain, A, of 2 and adjusting said gain sacrifices stability to some extent. Voltage reference 1406 is scaled by programmable potentiometer 1407 under control 1456 of a controlling system. Scaled voltage reference 1354, optionally scaled by resistor divider 1461, 1462 determines the full scale span of ADC 1405. Scaled reference 1354 is divided by 4 by resistors 1408 and 1409, optionally being digitally adjustable, before being used as the reference offset 1453 and then multiplied by 2 by amplifier 1401. This arrangement automatically places zero differential input as the midpoint of amplifier 1401 and ADC 1405 if optional resistors 1461 and 1462 are omitted. It provides full scale calibration by adjustment 1456 and by another optional adjustment and divider replacing 1408, 1409 allows scale and offset calibration.

In a calibrating mode of operation, the transmitting circuit transmits the maximum positive differential voltage and 1454 provides the largest possible single ended voltage. Comparator 1410 provides output 1455 to controlling system and controlling system controls 1456 scaling potentiometer 1407 up or down until the scaled voltage reference is equal to the maximum signal. Since Scaled VREF/2 is always the zero-differential result when only cable losses are considered, if the maximum positive differential signal obtains Scaled VREF, the maximum negative differential signal will obtain 0 and the differential span +/−Vₘₐₓ is mapped to the full range of the ADC codes. In more precise applications the optional further adjustment of divider 1408, 1409 allows offset and scale calibration.

In normal mode of operation a time varying signal is transmitted by the transmitter and signal 1454 will always be in the range ground <1454<1354 provided the analog signal does not exceed +/−Vₘₐₓ differentially and is within the common mode input range of 1401. The result is a dynamically self-calibrated ADC input that corrects for variations in signal losses between transmitter and receiver. Optional adjustment 1404 further allows large scale gain corrections but is not required.

In embodiments resistors 1408 and 1409 could be replaced with a programmable potentiometer that could be used to create an offset of the differential to single ended transformation. In systems wherein the differential signal is proportional to the dBm level of received radio wave signals, differenced in channel to channel gain may be compensated by first calibrating the full scale reference 1354 and then using a radio frequency calibration to provide a known RF signal level and adjusting the offset such that the ADC code associated with voltage 1454 relative to reference 1354 corresponds to the expected ADC code for the calibration RF signal level.

In an exemplary case where the transmitter 510 has a gain of 2, the open circuit voltage is +/−2.048V differential, the nominal loaded voltage under perfect match is +/−1.024V, the divider ratio of resistors 1311 is B, and the receiving amplifier 1401 gain is 2, the signal 1455 will be Scaled_VREF/2+2*B*(+/−1.024)*E, where E is approximately 1 but accounts for component tolerances and cable resistance. When the maximum signal is transmitted the signal is 2*B*E*1.024+Scaled VREF/2. Scaled_VREF is adjusted responsive to variations in E. VREF of reference 1406 is chosen to be slightly larger than 2BE*1.024 at the highest value of E, e.g. 1.015 for 15% errors. If VREF is chosen to be 1.024V for convenience, then B should be chosen as 0.25/1.015 or 0.2463. Values of E giving lower voltages are then readily addressed by scaling VREF downward.

In some embodiments, the control signal 1457 would be modified to adjust the wiper setting of 1404 to control the gain of amplifier 1401. In preferred embodiments signal 1454 is also fed to a comparator and compared to divided reference 1354. By altering the divider ratio, the scaled reference to the ADC may be adjusted so that a full scale signal gives a full scale ADC digital output. This may be performed at the start of every measurement. The divider is stepped up or down depending on the comparator 1410 state 1455 until the comparator output flips.

This will correct for gain errors in the transmitting amplifier, resistance variations of the transmitting electronic fuses, variations in cable resistance, variations in the resistor divider of the receiver load, variations of the gain of the receiving amplifier, and differences between the reference voltage of the transmitter and receiver.

In some embodiments, it may be known that the sensor does not use the full range of the ADC and it might be desirable to further divide 1354 between the comparator and ADC using resistors 1461 and 1462. This allows a full-scale reference voltage to be used to calibrate the transmission channel but a smaller maximum sensor response to provide full scale digital results. For example, logarithmic envelope detector AD8319 with scaling resistors can be made to output 2.048V at the noise floor, but the saturated RF signal output might not fall below 0.512V. Inverting the signal while creating a differential signal gives −1.024V to 0.512V and the receiver gives 0V to 0.766V by way of nonlimiting example. Dividing the scaled reference by ¾ would obtain a full scale ADC code for the saturating RF level and zero ADC code at the noise floor.

Resistors 1308 and 1309 apply one fourth of the scaled reference as a voltage offset for the single ended result 1455 in amplifiers wherein the reference is also multiplied by the gain. Other specific amplifiers might require a ratio of ½ for example. If two DC calibration voltages, for example, 0V differential and full-scale differential, are sent, then an optional control signal; and digital potentiometer could replace these resistors to calibrate both the slope and intercept.

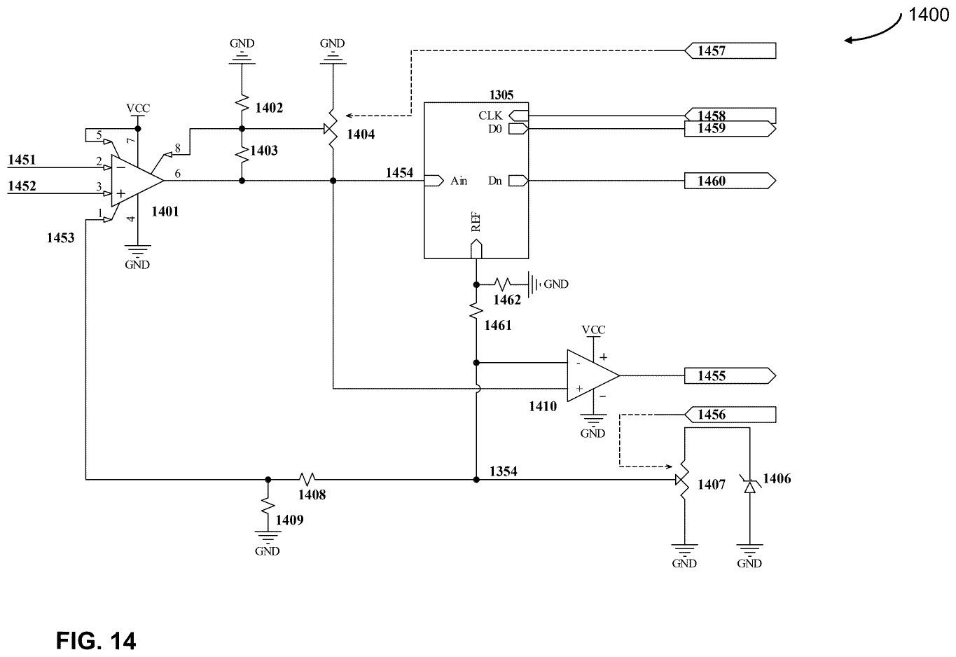

FIG. 15 shows an alternate transmitter in which the gain of the log detector 1501 is digitally adjusted by control 1557 using digital potentiometer 1503 and the offset of the differential signal is optionally adjusted by control 1556 using digital potentiometer 1510 to adjust offset 1553. While such embodiments would allow finer calibration of the system, introducing excessive intelligence into the sensor will impact long term reliability.

In more detail, FIG. 15 shows a transmitting circuit 1500 for the analog signal at the sensor end of a cable having active trimming. Radio frequency signal 1551 is converted to baseband signal by logarithmic envelope detector 1501 to create baseband signal 1552. The gain of detector is set by the ratio of resistor 1505 to the parallel combination of resistor 1504 and digitally controllable resistor 1503 controlled by gain control 1557, allowing compensation for the part to part variations of detector 1501.

Voltage reference 1511 is scaled by digitally controllable potentiometer 1510 controlled by offset control 1556 to create reference offset 1553. Amplifier 1502 with gain determined by resistors 1506-1509 drives differential lines 1554, 1555 through matching and protection circuit.

As discussed in FIG. 7A et al., electronic fuse or transient blocking unit 1515 disconnects the circuit on an overvoltage condition that is clamped by Zener diodes 1518 and 1519. Common mode interference is filtered by choke 1514. Optional overvoltage protection is provided by varistors 1516 and 1517. Electrical match is adjusted by resistors 1512 and 1513.

The result is a subsystem to convert a radio frequency signal into a low frequency signal representing the time varying amplitude of the radio frequency signal, presenting the low frequency signal as a differential voltage with digitally controlled offset 1556 and slope 1557.

In a calibration process, first a high and then a low amplitude radio frequency signal are applied and the slope of the resulting output voltage with respect to the amplitudes is determined. Gain adjustment 1557 is adjusted to correct the gain. A nominal signal intended to provide zero differential output is applied and offset correction control 1556 is adjusted to obtain zero output. In embodiments these adjustments are performed at final test of a system and the settings are remembered. In other embodiments, a reference signal, by way of non-limiting example a built in self-test simulation or synthesis of partial discharge, is applied and the offsets are adjusted so that the sensor indicates the value associated with the calibration or normalization source.

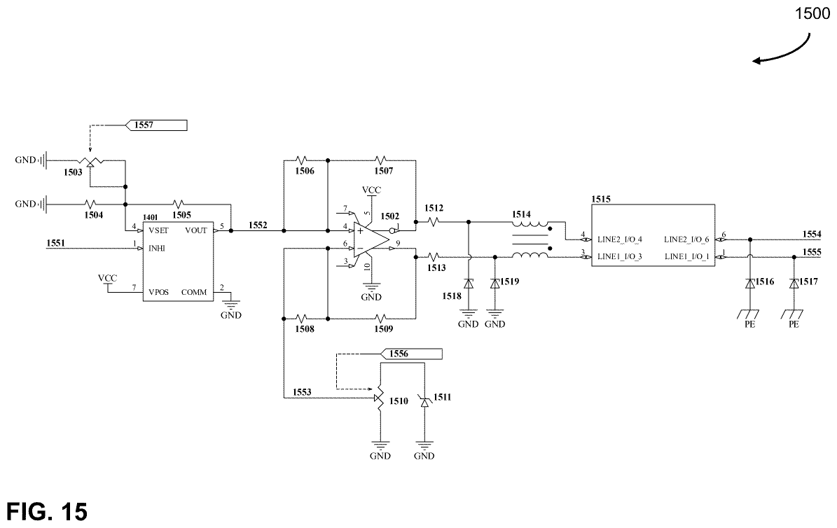

FIG. 16 shows a transmitting circuit 1600 sending digitized data for improved noise immunity. Antennas 101 and 111 are filtered 102 and 112 and selected by switch 104. The selected signal is amplified 103 and converted to baseband using a logarithmic envelope detector 105 by way of nonlimiting example. In some embodiments detector 105 uses a slope correction scheme as seen in FIG. 15. Detected signal is converted by converter 1601 and then serialized 1602 to a differential signal 1651 such as LVDS. The differential signal would be impedance matched and protected using, by way of nonlimiting example, the circuit of FIG. 7A. Any monotonic envelope detector may be used if the ADC has sufficient significant bits.

A 10-bit ADC at 60 M samples per second would require transmitting on the order of 600 M bits per second plus framing and optional error correction bits, which is compatible with high speed twisted pair cables. Linear detectors could be considered. To attain 60 dB of dynamic range at least 10 meaningful bits of ADC resolution are needed and more bits would be preferred, although transmitting 10 bits could be sufficient.

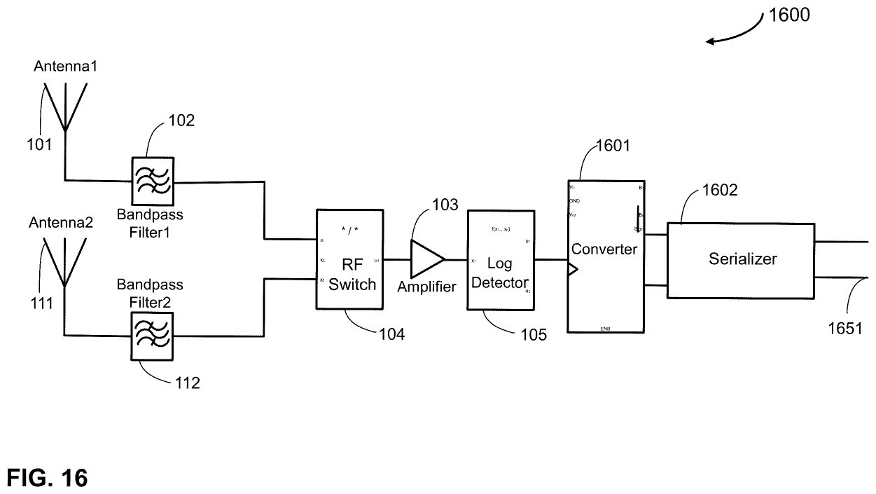

FIG. 17 shows a partial discharge system 1700 with measurement system integrated to smart sensor. Smart sensors 1731-1738 monitor radio signals for partial discharge and optionally one or more of ambient temperature, humidity, dew point, ultrasonic partial discharge, UV partial discharge, surface contaminants, ambient dust, oil conductivity, oil dielectric constant, etc. Smart sensors are optionally connected to self-test PD sources 1741-1748. In embodiments the test element is integrated into the smart sensor. In other embodiments a remote unit is controlled through the smart sensor.

One or more smart sensors connect to measurement hub 1721 which controls the measurements and interprets the signals. In embodiments smart sensors transmit a plurality of baseband analog signals indicative of signals related to partial discharge as measured by radio signals, ultrasonic signals, UV signals and the like. In other embodiments smart sensors transmit digitized data. In yet other embodiments smart sensors perform all analysis (integrated), and hub 1721 is a data concentrator.

Measurement hub 1721 communicates with local human machine interface (HMI) 1711 which optionally collects other data from other measurement systems, such as conductor temperatures, voltages, and currents in an electrical asset. HMI optionally communicates with a cloud server 1760 which is a repository for historical data. Remote users may access historical and live data from the cloud via a remote visualization unit 1701, receiving alarms on abnormal conditions, observing trendline plots, and observing other visualization data as disclosed in this invention to allow informed decisions on predictive and preventative maintenance.

In the present invention, there is provided an ultra-high frequency (UHF) partial discharge (PD) smart sensor that includes multiband antenna and one or more of the following complimentary sensors for temperature, humidity, dust, audible sound, ultrasonic PD, pressure, and dew point. The signal processing brain is embedded in the UHF smart sensor, and smart sensors are powered and communicate on common bus. The signal processing brain is separated in Hub or HMI that supports multiple sensor inputs.

There is also a UHF PD smart sensor with means to self-calibrate and adjust of analog loss through different lengths of cable between antenna and Hub, where the cable is an industrial ethernet cable (shielded or un-shielded twisted pair), and where the cable is coax RF cable.

There is also a measurement hub with a phase input timing signal from the AC power, where phase timing is taken from available AC power local to switchgear, and where phase timing is taken from a CT on one of the phases.

In the present application, medium voltage is a term used in power systems and denotes voltages over 1000 Vrms and up to a limit that varies by national standards. The upper limit is typically 33 kV or 39 kV with some standards including 69 kV. In standards that define medium voltage, high voltage means any voltage higher than medium voltage. Safety standards generally do not define medium voltage and instead define low voltage as less than 1000 Vrms and high voltage as higher than this level. While the descriptions focused on medium voltage, the safety requirements and the need to measure partial discharge both exist for all voltages over 1000 Vrms. In the description and claims, we use high voltage to be inclusive of medium voltage systems.

Ultrahigh frequency shall comprise frequencies above 300 MHz. Baseband shall comprise frequencies below 150 MHz and preferably below 30 MHz.

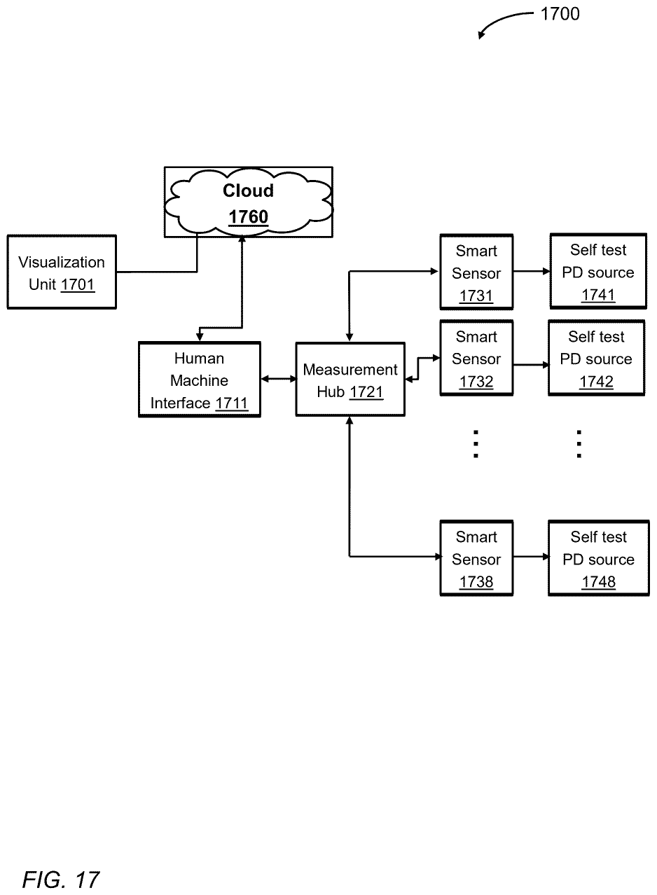

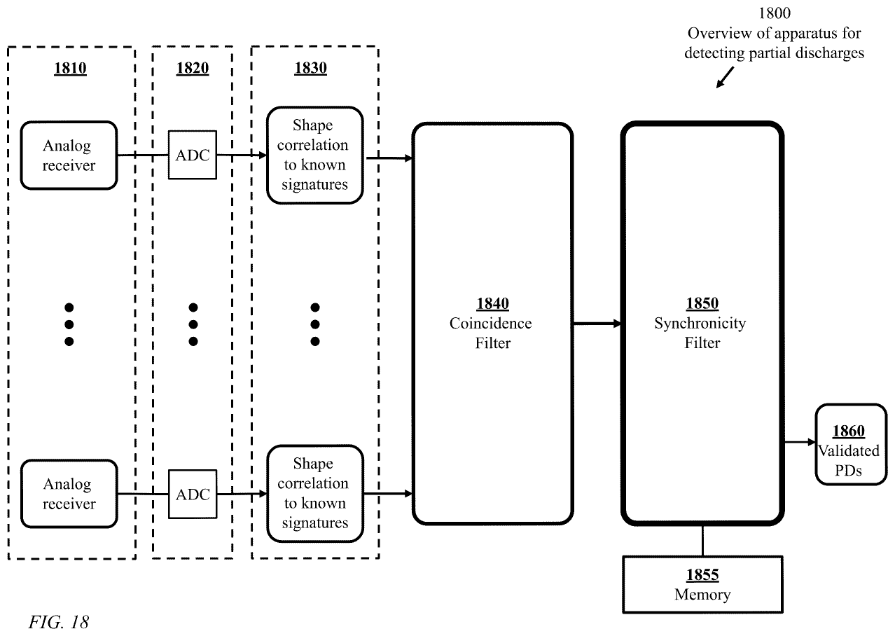

FIG. 18 shows a summary block diagram 1800 for a measurement hub employing analog transmission. The hub comprises at least two analog receivers 1810, coupled to at least two ADCs 1820, feeding logic implementing optional shape correlation 1830, coincidence filter 1840, and synchronicity filter 1850. Synchronicity filter compares the candidate PD signals from coincidence filter 1840 to prior power cycle PD data in memory 1855 to produce validated PDs 1860.

In other words, FIG. 18 presents an overview 1800 of a system for PD detection disclosed in the U.S. application Ser. No. 19/197,943 cited above. The system comprises an array 1810 of analog receivers, similar to the enhanced receivers (also call subcircuit) of the present invention. Each analog receiver comprises an antenna, a bandpass filter, and an envelope detector or logarithmic detector. An array 1820 of samplers and ADC (A/D) convertors produces digitized samples of the sensors' output signals. An array 1830 of correlators compares detected pulses with signatures of known PD classes for determining whether the pulses are potentially a result of a PD. A coincidence filter 1840 determines the extent of temporal coincidence of pulses detected from output signals of different analog receivers. A synchronicity filter 1850 further examines pulses that pass the coincidence test of the coincidence filter to determine an extent of recurrence in successive power-cycle periods (20 or 50/3 milliseconds). A memory 1855 maintains data relevant to trailing power cycles for determining the recurrence. Data relevant to validated PD incidences are held in a result memory 1860. Arrays 1820, 1830, 1840, 1850, and 1860 are constituents of a processing hub which detects occurrences of partial discharges based on information from the sensors.

Thus, embodiments of the present invention provide various methods and systems for detecting a partial discharge in the electric power equipment, and methods of operating the systems for detecting the partial discharge. A brief summary is provided below.

A system for detecting a partial discharge (PD) in electric power equipment is provided. The system comprises a sensor and a measurement hub interconnected through a cable. The sensor is located to enable receiving ultra-high frequency (UHF) signals that includes potential PD-induced electromagnetic (EM) signals. The sensor comprises at least one antenna and at least two envelope detectors (linear or logarithmic) connected to at least one of the at least one antenna through respective bandpass filters. The measurement hub comprises a computational platform and is located so as to allow safe access.

The bandpass filters are configured to derive at least two signals in two different frequency bands. The at least two envelope detectors are configured to simultaneously detect from the at least two signals respective at least two baseband signals. The cable is configured to transmit the at least two baseband signals on corresponding at least two signal lines of the cable from the sensor to the measurement hub.

The at least two baseband signals are analog baseband signals. In one implementation, the measurement hub comprises a receiver and an analog-to-digital converter (ADC). In another implementation, the sensor comprises an analog-to-digital converter (ADC) and a serializer for transmitting serial digital data to said measurement hub.

Preferably, with either of the two implementations, the sensor further comprises more bandpass filters than envelope detectors, and a RF switch for selecting, for each envelope detector, a respective bandpass filter.

The system further comprises additional one or more sensors of different types for detecting the partial discharge by alternative methods other than electromagnetic sensing, and an analog switch for selecting one of said additional one or more sensors.

The sensor is further configured to generate a calibration voltage as a calibration output of the sensor, the calibration output being selectable by an analog switch.

The system is further configured to transmits a signal representing a maximum voltage span as the calibration output. The measurement hub further comprises:
a reference circuit generating a local reference voltage exceeding the calibration response received by the receiver responsive to said maximum voltage span transmitted by said sensor;
a digitally controlled reference divider for scaling said local reference voltage to match a response of the receiver when receiving said maximum voltage span as said calibration output, to produce a digitally scaled reference voltage;
a comparison means for comparing said digitally scaled reference voltage and said received calibration response; and
a second voltage scaling means configured to apply a second scaled replica of said digitally scaled reference voltage as a common mode voltage offset of said receiver.

The system may use one or more of the following sensors: Temperature sensor; Humidity sensor; Dust sensor; Condensation sensor; Audible sound sensor; Ultrasonic PD sensor; Pressure sensor; and Dew point sensor.

The system further comprises a built-in self-test module, proximate the sensor, the built-in self-test module being able to synthesize a UHF signature of the partial discharge under command of said measurement hub. The sensor is configured to report measurements before, during, and after an activation of said built-in self-test module. The measurement hub is configured to compare the measurements; and assess a health of said sensor based on deviations of said measurements.

Also a method of operating the system for detecting a partial discharge is provided. The method comprises:
(a) placing a sensor so as to receive ultra-high frequency (UHF) signals related to the partial discharge, the sensor comprising at least one antenna and at least two envelope detectors connected to at least one of said at least one antenna through respective bandpass filters;
(b) placing a measurement hub located so as to allow safe access and having a computational platform;
(c) interconnecting the sensor and the measurement hub by a cable;
wherein:
(d) the step (a) comprises deriving, by said at least one antenna, at least two UHF signals in two different frequency bands;
(e) the step (a) further comprises simultaneously detecting, by said at least two envelope detectors, said at least two UHF signals respectively, providing respective at least two baseband signals; and
(f) transmitting a facsimile of said at least two baseband signals on corresponding at least two signal lines of said cable from said sensor to said measurement hub.

The method further comprises a calibration procedure, performed after the step (c) and before the steps (d), the calibration procedure comprising:
(i) by the measurement hub, instructing the sensor to output a full-scale calibration signal;
(ii) at a receiver of the measurement hub, receiving the full-scale calibration signal, and presenting it to a comparator of the measurement hub;
(iii) by a computational platform of the measurement hub, adjusting a first scale factor of a reference voltage until the full-scale calibration signal and a scaled replica of the reference voltage are sufficiently equal; and
   (iv) repeating the steps (i) to (iii) until an error between the full-scale calibration signal and the scaled replica of the reference voltage is within a predefined first tolerance.

The method further comprises performing the following steps by the measurement hub, after the step (c) and before the steps (d):
(i) instructing said sensor to output a half-scale calibration signal;
(ii) monitoring a response from an analog-to-digital converter of the measurement hub to said half-scale calibration signal; and
(iii) adjusting a second scale factor of a reference voltage until the half-scale calibration signal obtains a half-scale digital reading from an analog-to-digital (ADC) converter of said measurement hub; and
(iv) repeating the steps (i) to (iii) until said half-scale digital reading is within a predefined second tolerance.

The method further comprises a calibration procedure, performed after the step (c) and before the steps (d), the calibration procedure comprising:
(i) by the measurement hub, instructing the sensor to output a full-scale calibration signal;
(ii) at a receiver of the measurement hub, receiving the full-scale calibration signal, and presenting it to a comparator of the measurement hub;
(iii) by a computational platform of the measurement hub, adjusting a first scale factor of a reference voltage until the full-scale calibration signal and a scaled replica of the reference voltage are sufficiently equal;
   (iv) repeating the steps (i) to (iii) until an error between the full-scale calibration signal and the scaled replica of the reference voltage is within a predefined first tolerance;
(v) instructing said sensor to output a half-scale calibration signal;
(vi) monitoring a response from an analog-to-digital converter of the measurement hub to said half-scale calibration signal;
(vii) adjusting a second scale factor of a reference voltage until the half-scale calibration signal obtains a half-scale digital reading from an analog-to-digital (ADC) converter of said measurement hub;
(viii) repeating the steps (v) to (vii) until said half-scale digital reading is within a predefined second tolerance; and
(ix) repeating the steps (i) through (viii) until both the full-scale calibration signal and said half-scale digital reading are within said respective predefined first and second tolerances.

The method further comprises:
providing more bandpass filters than envelope detectors for said sensor, and a radio frequency switch for selecting a respective bandpass filter for each envelope detector;
prior to the step (c), by the measurement hub, performing the following steps:
   commanding said sensor to scan available bandpass filter responses by controlling a selection of frequency bands coupled to each envelope detector by respective RF switches;
   determining the average signal noise levels for each envelope detector; and
   selecting a bandpass filter response from each envelope detector to provide the lowest average signal noise level for each envelope detector, provided each frequency band is used in one detector only.

The method further comprises:
placing a built-in self-test module proximate to said sensor and connected to said measurement hub;
after the step (c), by the measurement hub, performing the following:
commanding said built-in self-test module to output a pattern of simulated partial discharge;
scanning available bandpass filter responses by controlling a selection of frequency bands coupled to each envelope detector by respective RF switches;
determining the most often recurring signal levels with said built-in self-test module idle and recurring signal levels with said built-in self-test module creating partial discharge signatures for each envelope detector; and
selecting a bandpass filter response from each envelope detector to provide the highest ratio of the recurring partial discharge signal ratio to the recurring idle signal level for each envelope detector, provided each frequency band is assigned to one detector only.

The method further comprising, by the measurement hub:
detecting said least two UHF signals in two different frequency bands;
correlating said two UHF signals to determine a confidence level that said two UHF signals are representative of the partial discharge;
otherwise, reporting unconfirmed partial discharge.

The method further comprises:
by said measurement hub, upon detecting the partial discharge, measuring the partial discharge by at least one alternate PD sensor using an alternative method other than a UHF method; and
using results from said at least one alternate sensor to confirm a presence of the partial discharge.

The method further comprises the following steps, after the step (c):
placing built-in self-test module proximate to said sensor and connected to said measurement hub;
by the measurement hub, commanding the built-in self-test module to output a pattern of simulated partial discharge;
measuring a response of the system for detecting a partial discharge to said simulated partial discharge; and
validating a proper functioning of the system for detecting a partial discharge based on the measured response.

Also there is provided an ultra high frequency (UHF) sensor for detecting a partial discharge (PD) signal, comprising at least two receivers for simultaneously obtaining corresponding at least two narrowband signals corresponding to respective frequency bands of the partial discharge signal, and a coincidence filter for detecting a temporal coincidence of said at least two narrowband signals, thereby indicating a presence of the partial discharge signal.

The UHF sensor may be further augmented by one or more of the following sensors: Temperature sensor, Humidity sensor, Dust sensor, Audible sound sensor, Ultrasonic PD sensor, Ultraviolet PD sensor, Pressure sensor, Gas sensor, and Dew point sensor.

The UHF sensor further comprises means for self-calibration, for accommodating different lengths of a cable between antennas of said at least two receiver and a hub and component variations in protective and matching circuits. The cable is typically a multi-pair a twisted pair, for example, Ethernet cable.

Further, there is provided a method for detecting a partial discharge signal, comprising at least two receivers, obtaining corresponding at least two narrowband signals corresponding to respective frequency bands of the partial discharge signal, and a coincidence filter, detecting a temporal coincidence of said at least two narrowband signals, thereby indicating a presence of the partial discharge signal.

The method further comprises identifying a recurrence of the partial discharge signal at substantially the same time or phase relative to the power voltage waveform over a plurality of past power cycles, thereby validating the partial discharge signal.

The method further comprises classifying the partial discharge signal. The method further comprises visualizing the partial discharge signal.

Also a system for detecting a partial discharge signal is provided, comprising at least two receivers for obtaining corresponding at least two narrowband signals corresponding to respective frequency bands of the partial discharge signal, and a coincidence filter for detecting a temporal coincidence of said at least two narrowband signals, thereby indicating a presence of the partial discharge signal.

The system further comprises a means for identifying a recurrence of the partial discharge signal at substantially the same time or phase relative to the power voltage waveform over a plurality of past power cycles, thereby validating the partial discharge signal.

The system further comprises a means for classifying the partial discharge signal. The system further comprises a means for visualizing the partial discharge signal.

In the embodiments of the present invention, the partial discharge signals are detected using analysis in which a plurality of bandpass filtered interpretations of said signals having different passbands are measured and different frequency content of said signals are compared to one another for coincidence of arrival time and diversity of frequency content by a coincidence filter. The outputs of said coincidence filter are compared to previous outputs of said coincidence filter at a corresponding phase point in a plurality of past power cycles, values representing the recurring level of partial discharge over said plurality of past power cycles are determined by a synchronicity filter. The outputs of said synchronicity filter are provided as the level of discharge at the phase of the power cycle at which said signal was observed.

The coincidence filter may use procedural logic to ignore signals that are not present in a majority of frequency channels within a desired degree of uniformity of amplitude. The coincidence filter may alternately use correlation methods to determine the degree to which signals are represented in said frequency bands. This may be performed by multiplication of signals wherein a linear detector is used or wherein a logarithmic signal is measured and samples are converted to linear scale as they are received, for example, using a lookup table, or in the logarithmic domain by addition. The time signal is optionally correlated against an expected time signature of partial discharge to provide an output indicative of the amplitude of said signature contained in said signal. The time signal may further be correlated against a plurality of expected time signatures of a plurality of classifications of partial discharge to provide a plurality of outputs indicative of the amplitudes of each of said signatures contained in said signature. The system may process all classifications in parallel as a superposition or may validate only the most likely class.

The outputs of said synchronicity filter are accumulated into time bins comprising a plurality of the sampling period, wherein the width of the time or phase bins is, by way of nonlimiting example, 30 degrees with six bins corresponding to the peak positive and negative line to earth voltages and six bins corresponding to the peak positive and negative line to line voltages of a three phase power system. The offsets of the 30 degree bins are optionally adjusted to be in advance of the peak voltages, wherein said outputs of said synchronicity filter are assigned to an accumulator for said bin. Alternately the said outputs may be counted in a two dimensional memory with one dimension representing time intervals and the other dimension representing amplitude intervals.

The samples are accumulated over a plurality of power frequency periods, wherein the number of samples in the selected amplitude bin corresponding to the time or phase value is incremented with each new event. In reading out the time series of partial discharges as average accumulated charge per time interval, a linear signal related to the accumulated partial discharge is approximated by first multiplying the count and the nominal linear value of the amplitude bin, second summing said product over all amplitude bins at a given time or phase, and third dividing the sum by the number of power cycles that were accumulated.

In some embodiments, the outputs of the coincidence filter comprise a value for each frequency band indicating the signal strength in said band and the outputs of said synchronicity filters provide phase resolved partial discharge data components contributed in each frequency band.

In some embodiments, the outputs of the coincidence filter comprise a value for each classification signature indicating the signal strength for said classification and the outputs of said synchronicity filters provide phase resolved partial discharge data components contributed by each classification.

The outputs of the synchronicity filter for each frequency band are input to a clustering analyzer and the relative strengths of the frequency bands are used to classify the discharge.

Data from a plurality of power cycles are accumulated into an array of pixels having one dimension corresponding to time or phase bins and the other dimension corresponding to amplitude bins accumulating samples from a plurality of power cycles, and presenting the number of samples per pixel indicated by the brightness of the pixel.

In some embodiments, the plurality of power cycles are accumulated into up to three arrays of pixels each array corresponding to a frequency band or a classification of partial discharge each array having one dimension correspond to time or phase bins and the other dimension correspond to amplitude bins accumulating samples from a plurality of power cycles, and each array presenting the number of samples per pixel indicated by the brightness of one of red, green or blue for the pixel, the color of each pixel indicating a classification and the brightness indicating a level of partial discharge. In related embodiments, a single array holds RGB 24 bit numbers assembled from the three signals.

In some embodiments, the plurality of power cycles are accumulated into a plurality of arrays of pixels with each array corresponding to a classification of partial discharge, each array having one dimension correspond to time or phase bins and the other dimension correspond to amplitude bins accumulating samples from a plurality of power cycles, and each array presenting the number of samples per classification displayed in a three dimensional scatter plot with the least significant classifications in the background and the most important classifications in the foreground.

Also a system for detecting the partial discharge is provided, including an ultra-high frequency (UHF) partial discharge (PD) smart sensor that includes multiband antenna and is augmented by one or more of the following complimentary sensors: temperature, humidity, dust, audible sound, ultrasonic PD, pressure and dew point, just to name a few.

In the smart sensor, the signal processing options are controlled by a set of digital control lines that may be set based on commands over a pair of wires and the sensor power is provided on another pair of wires.

The brain is embedded in the safe instrumentation compartment, where frequent service requirements of digital computing devices may be addressed safely and without impairing the electrical process.

In the smart sensor, the signal processing brain in the separately located Hub or HMI supports multiple sensor inputs, allowing the cost of signal processing to be shared over may sensor locations.

Additionally, as described in detail above, there is provided an ultra-high frequency (UHF) partial discharge (PD) smart sensor with means to self-calibrate and adjust the analog loss through different lengths of cable between antenna and Hub and component variations of protective circuit elements. The cable is industrial ethernet cable (shielded or un-shielded twisted pair).

The UHF PD smart sensor has a phase input timing signal from AC power.

Thus, an improved method and system for monitoring and detecting the partial discharge for electric power equipment and methods of operating the system have been provided.

Methods of the embodiment of the invention are performed using one or more hardware processors, executing processor-executable instructions causing the hardware processors to implement the processes described above. Computer executable instructions may be stored in processor-readable storage media such as hard disks, Flash ROMS, non-volatile ROM, and RAM. A variety of processors, such as microprocessors, digital signal processors, and gate arrays, may be employed. Systems of the embodiments of the invention may be implemented as any of a variety of suitable circuitry, such as one or more microprocessors, digital signal processors (DSPs), application-specific integrated circuits (ASICs), field programmable gate arrays (FPGAs), discrete logic, software, hardware, firmware or any combinations thereof. When modules of the systems of the embodiments of the invention are implemented partially or entirely in software, the modules contain a memory device for storing software instructions in a suitable, non-transitory computer-readable storage medium, and software instructions are executed in hardware using one or more processors to perform the techniques of this disclosure.

It should be noted that methods and systems of the embodiments of the invention and data streams described above are not, in any sense, abstract or intangible. Instead, the data is necessarily presented in a digital form and stored in a physical data-storage computer-readable medium, such as an electronic memory, mass-storage device, or other physical, tangible, data-storage device and medium. It should also be noted that the currently described data-processing and data-storage methods cannot be carried out manually by a human analyst, because of the complexity and vast numbers of intermediate results generated for processing and analysis of even quite modest amounts of data. Instead, the methods described herein are necessarily carried out by electronic computing systems having processors on electronically or magnetically stored data, with the results of the data processing and data analysis digitally stored in one or more tangible, physical, data-storage devices and media.

What is claimed is:

1.-40. (canceled)

41. A system for detecting a partial discharge in electric power equipment, the system comprising:
a sensor located so as to receive ultra high frequency (UHF) signals related to the partial discharge, comprising at least one antenna and at least two envelope detectors connected to at least one of said at least one antenna through respective bandpass filters;
a measurement hub located so as to allow safe access and having a computational platform;
the sensor and the measurement hub being interconnected by a cable;
wherein:
said at least one antenna is configured to derive at least two UHF signals in two different frequency bands;
said at least two envelope detectors are configured to simultaneously detect from said at least two UHF signals respective at least two baseband signals; and
said cable is configured to transmit said at least two baseband signals on corresponding at least two signal lines of said cable from said sensor to said measurement hub.

42. The system of claim 41, wherein said at least two baseband signals are analog baseband signals, and said measurement hub further comprises a receiver and an analog-to-digital converter (ADC).

43. The system of claim 41, wherein said sensor further comprises an analog-to-digital converter (ADC) and a serializer for transmitting serial digital data to said measurement hub.

44. The system of claim 42, wherein said sensor further comprises more bandpass filters than envelope detectors, and a RF switch for selecting a respective bandpass filter for each envelope detector.

45. The system of claim 43, wherein said sensor further comprises more bandpass filters than envelope detectors, and a RF switch for selecting a respective bandpass filter for each envelope detector.

46. The system of claim 42, further comprising additional one or more sensors of different types for detecting the partial discharge by alternative methods other than an electromagnetic sensing, and an analog switch for selecting one of said additional one or more sensors or said sensor.

47. The system of claim 43, further comprising additional one or more sensors of different types for detecting the partial discharge by alternative methods other than an electromagnetic sensing, and an analog switch for selecting one of said additional one or more sensors or said sensor.

48. The system as claimed in claim 42, wherein said sensor is configured to generate a calibration voltage as a calibration output of said sensor, the calibration output being selectable by an analog switch.

49. The system as claimed in claim 48, wherein said output transmits a signal representing a maximum voltage span as the calibration output, the measurement hub further comprises:
a reference circuit generating a local reference voltage exceeding the calibration response received by said receiver responsive to said maximum voltage span transmitted by said sensor;
a digitally controlled reference divider for scaling said local reference voltage to match a response of the receiver when receiving said maximum voltage span as said calibration output, to produce a digitally scaled reference voltage;
a comparison means for comparing said digitally scaled reference voltage and said received calibration response; and
a second voltage scaling means configured to apply a second scaled replica of said digitally scaled reference voltage as a common mode voltage offset of said receiver.

50. A system of 41, further comprising one or more of the following sensors:
Temperature sensor;
Humidity sensor;
Dust sensor;
Condensation sensor;
Audible sound sensor;
Ultrasonic PD sensor;
Pressure sensor; and
Dew point sensor.

51. The system of claim 41, further comprising a built-in self-test module, proximate said sensor, said built-in self-test module being able to synthesize a UHF signature of the partial discharge under command of said measurement hub, wherein:
said sensor is configured to report measurements before, during, and after an activation of said built-in self-test module;
said measurement hub is configured to:
compare said measurements; and
assess a health of said sensor based on deviations of said measurements.

52. A method of operating a system for detecting a partial discharge, the method comprising:
(a) placing a sensor so as to receive ultra high frequency (UHF) signals related to the partial discharge, the sensor comprising at least one antenna and at least two envelope detectors connected to at least one of said at least one antenna through respective bandpass filters;
(b) placing a measurement hub located so as to allow safe access and having a computational platform;
(c) interconnecting the sensor and the measurement hub by a cable;
wherein:
(d) the step (a) comprises deriving, by said at least one antenna, at least two UHF signals in two different frequency bands;
(e) the step (a) further comprises, by said at least two envelope detectors, simultaneously detecting from said at least two UHF signals respective at least two baseband signals; and
(f) transmitting a facsimile of said at least two baseband signals on corresponding at least two signal lines of said cable from said sensor to said measurement hub.

53. The method of claim 52, further comprising a calibration procedure, performed after the step (c) and before the steps (d), the calibration procedure comprising:
(i) by the measurement hub, instructing the sensor to output a full-scale calibration signal;
(ii) at a receiver of the measurement hub, receiving the full-scale calibration signal, and presenting it to a comparator of the measurement hub;
(iii) by a computational platform of the measurement hub, adjusting a first scale factor of a reference voltage until the full-scale calibration signal and a scaled replica of the reference voltage are sufficiently equal; and
(iv) repeating the steps (i) to (iii) until an error between the full-scale calibration signal and the scaled replica of the reference voltage is within a predefined first tolerance.

54. The method of claim 52, further comprising performing the following steps by the measurement hub, after the step (c) and before the steps (d):
(i) instructing said sensor to output a half-scale calibration signal;
(ii) monitoring a response from an analog-to-digital converter of the measurement hub to said half-scale calibration signal; and
(iii) adjusting a second scale factor of a reference voltage until the half-scale calibration signal obtains a half-scale digital reading from an analog-to-digital (ADC) converter of said measurement hub; and
(iv) repeating the steps (i) to (iii) until said half-scale digital reading is within a predefined second tolerance.

55. The method of claim 52, further comprising a calibration procedure, performed after the step (c) and before the steps (d), the calibration procedure comprising:
(i) by the measurement hub, instructing the sensor to output a full-scale calibration signal;
(ii) at a receiver of the measurement hub, receiving the full-scale calibration signal, and presenting it to a comparator of the measurement hub;
(iii) by a computational platform of the measurement hub, adjusting a first scale factor of a reference voltage until the full-scale calibration signal and a scaled replica of the reference voltage are sufficiently equal;
(iv) repeating the steps (i) to (iii) until an error between the full-scale calibration signal and the scaled replica of the reference voltage is within a predefined first tolerance;
(v) instructing said sensor to output a half-scale calibration signal;
(vi) monitoring a response from an analog-to-digital converter of the measurement hub to said half-scale calibration signal;
(vii) adjusting a second scale factor of a reference voltage until the half-scale calibration signal obtains a half-scale digital reading from an analog-to-digital (ADC) converter of said measurement hub;
(viii) repeating the steps (v) to (vii) until said half-scale digital reading is within a predefined second tolerance; and
(ix) repeating the steps (i) through (viii) until both the full scale calibration signal and said half-scale digital reading are within said respective predefined first and second tolerances.

56. The method of 52, further comprising:
providing more bandpass filters than envelope detectors for said sensor, and a radio frequency switch for selecting a respective bandpass filter for each envelope detector;
prior to the step (c), by the measurement hub, performing the following steps:
commanding said sensor to scan available bandpass filter responses by controlling a selection of frequency bands coupled to each envelope detector by respective RF switches;
determining the average signal noise levels for each envelope detector; and
selecting a bandpass filter response from each envelope detector to provide the lowest average signal noise level for each envelope detector, provided each frequency band is used in one detector only.

57. The method of claim 52, further comprising:
placing a built-in self-test module proximate to said sensor and connected to said measurement hub;
after the step (c), by the measurement hub, performing the following:
commanding said built-in self-test module to output a pattern of simulated partial discharge;
scanning available bandpass filter responses by controlling a selection of frequency bands coupled to each envelope detector by respective RF switches;
determining the most often recurring signal levels with said built-in self-test module idle and recurring signal levels with said built-in self-test module creating partial discharge signatures for each envelope detector; and
selecting a bandpass filter response from each envelope detector to provide the highest ratio of the recurring partial discharge signal ratio to the recurring idle signal level for each envelope detector, provided each frequency band is assigned to one detector only.

58. The method of claim 52, further comprising, by said measurement hub:
detecting said least two UHF signals in two different frequency bands;
correlating said two UHF signals to determine a confidence level that said two UHF signals are representative of the partial discharge;
otherwise, reporting unconfirmed partial discharge.

59. The method of 58, further comprises:
by said measurement hub, upon detecting the partial discharge, measuring the partial discharge by at least one alternate PD sensor using an alternative method other than a UHF method; and
using results from said at least one alternate sensor to confirm a presence of the partial discharge.

60. The method 52, further comprising the following steps, after the step (c):
placing built-in self-test module proximate to said sensor and connected to said measurement hub;
by the measurement hub, commanding the built-in self-test module to output a pattern of simulated partial discharge;
measuring a response of the system for detecting a partial discharge to said simulated partial discharge; and
validating a proper functioning of the system for detecting a partial discharge based on the measured response.
